(19) United States
(12) Patent Application Publication
(10) Pub. No.: US 2026/0221166 A1
(43) Pub. Date: Jul. 30, 2026

(54) SEMICONDUCTOR MEMORY DEVICE

(71) Applicant: Kioxia Corporation, Tokyo (JP)

(72) Inventors: Kouji MATSUO, Ama Aichi (JP); Shunichi SENO, Yokkaichi Mie (JP)

(73) Assignee: Kioxia Corporation, Tokyo (JP)

(21) Appl. No.: 19/305,587

(22) Filed: Aug. 20, 2025

(30) Foreign Application Priority Data
Jan. 24, 2025 (JP) 2025-010854

(51) Int. Cl. G11C 5/06; G11C 16/04; G11C 16/10; G11C 16/28; G11C 16/30; H10B 43/10; H10B 43/27; H10B 43/35; H10B 43/40

(52) U.S. Cl. CPC G11C 5/063; G11C 16/0483; G11C 16/10; G11C 16/28; G11C 16/30; H10B 43/10; H10B 43/27; H10B 43/35; H10B 43/40

(57) ABSTRACT

A semiconductor memory device according to an embodiment includes a stacked body in which a plurality of first insulating layers and a plurality of second insulating layers are alternately stacked, a plurality of channel layers, each of which is provided in each of the plurality of first insulating layers so as to extend in a first direction along the plurality of first insulating layers, a word line that extends in the stacked body in a stacking direction of the stacked body so as to intersect the plurality of channel layers, a plurality of bit lines, each of which is connected to each of the plurality of channel layers, and a plurality of booster circuits, each of which is provided in each of the plurality of first insulating layers so as to be connected to each of the plurality of bit lines.

### CROSS-REFERENCE TO RELATED APPLICATIONS

This application is based upon and claims the benefit of priority from Japanese Patent Application No. 2025-010854, filed on Jan. 24, 2025; the entire contents of which are incorporated herein by reference.

### FIELD

Embodiments described herein relate generally to a semiconductor memory device.

### BACKGROUND

In a semiconductor memory device including a plurality of memory cells connected to a common word line, a low-level voltage is supplied to a memory cell to be written via a bit line, and a high-level voltage is applied to a memory cell not to be written via the bit line. As a result, writing of data to the memory cell to be written is allowed, and writing of data to the memory cell not to be written is suppressed.

For example, a power supply voltage is used as the high-level voltage applied to the memory cell not to be written. At this time, a higher voltage level enables further reliable suppression of writing, and therefore, there is a demand for further increasing the voltage applied to the memory cell not to be written. However, in this case, it is necessary to increase the voltage of a sense amplifier module that supplies a voltage to the bit line, causing an increase in the chip area of the semiconductor memory device.

### BRIEF DESCRIPTION OF THE DRAWINGS

FIG. 1 is a block diagram of a semiconductor memory device according to an embodiment;

FIG. 2 is a schematic circuit diagram illustrating an exemplary configuration of a block included in the semiconductor memory device according to an embodiment;

FIG. 3 is a circuit diagram illustrating an exemplary configuration of a sense amplifier circuit and latch circuits included in the semiconductor memory device according to an embodiment;

FIG. 4 is a schematic diagram illustrating a write operation of the semiconductor memory device according to an embodiment;

FIG. 5 is a circuit diagram illustrating an exemplary configuration of a booster circuit included in the semiconductor memory device according to an embodiment;

FIGS. 6A and 6B are schematic diagrams each illustrating an operation of the booster circuit included in the semiconductor memory device according to an embodiment;

FIGS. 7A and 7B are schematic diagrams each illustrating an exemplary configuration of a partial area of the semiconductor memory device according to an embodiment;

FIG. 8 is a plan view illustrating an exemplary configuration of a partial area of the semiconductor memory device according to an embodiment;

FIG. 9 is a perspective cross-sectional view illustrating an exemplary configuration including a block region of the semiconductor memory device according to an embodiment;

FIGS. 10A to 10C are schematic diagrams each illustrating an exemplary configuration of a hook-up region included in the semiconductor memory device according to an embodiment;

FIGS. 11A to 11D are schematic diagrams each illustrating an example of each unit included in the booster circuit of the semiconductor memory device according to an embodiment;

FIGS. 12A and 12B are plan views illustrating an exemplary physical configuration of a booster circuit included in the semiconductor memory device according to an embodiment;

FIG. 13Aa to 13Bd are schematic diagrams sequentially illustrating parts of an exemplary procedure of a method of manufacturing a semiconductor memory device according to an embodiment;

FIG. 14Aa to 14Bd are schematic diagrams sequentially illustrating parts of an exemplary procedure of the method of manufacturing a semiconductor memory device according to an embodiment;

FIG. 15Aa to 15Bd are schematic diagrams sequentially illustrating parts of an exemplary procedure of the method of manufacturing a semiconductor memory device according to an embodiment;

FIG. 16Aa to 16Bd are schematic diagrams sequentially illustrating parts of an exemplary procedure of the method of manufacturing a semiconductor memory device according to an embodiment;

FIG. 17Aa to 17Bd are schematic diagrams sequentially illustrating parts of an exemplary procedure of the method of manufacturing a semiconductor memory device according to an embodiment;

FIG. 18Aa to 18Bd are schematic diagrams sequentially illustrating parts of an exemplary procedure of the method of manufacturing a semiconductor memory device according to an embodiment;

FIG. 19Aa to 19Bd are schematic diagrams sequentially illustrating parts of an exemplary procedure of the method of manufacturing a semiconductor memory device according to an embodiment;

FIG. 20Aa to 20Bd are schematic diagrams sequentially illustrating parts of an exemplary procedure of the method of manufacturing a semiconductor memory device according to an embodiment;

FIG. 21Aa to 21Bd are schematic diagrams sequentially illustrating parts of an exemplary procedure of the method of manufacturing a semiconductor memory device according to an embodiment;

FIG. 22Aa to 22Bd are schematic diagrams sequentially illustrating parts of an exemplary procedure of the method of manufacturing a semiconductor memory device according to an embodiment;

FIG. 23Aa to 23Bd are schematic diagrams sequentially illustrating parts of an exemplary procedure of the method of manufacturing a semiconductor memory device according to an embodiment; and

FIGS. 24A and 24B are circuit diagrams illustrating an exemplary configuration of a booster circuit included in a semiconductor memory device according to a modification of the embodiment.

### DETAILED DESCRIPTION

A semiconductor memory device according to an embodiment includes a stacked body in which a plurality of first insulating layers and a plurality of second insulating layers are alternately stacked, a plurality of channel layers, each of which is provided in each of the plurality of first insulating layers so as to extend in a first direction along the plurality of first insulating layers, a word line that extends in the stacked body in a stacking direction of the stacked body so as to intersect the plurality of channel layers, a plurality of bit lines, each of which is connected to each of the plurality of channel layers, and a plurality of booster circuits, each of which is provided in each of the plurality of first insulating layers so as to be connected to each of the plurality of bit lines.

Embodiments of the present invention will be described in detail below with reference to the drawings. Note that the present invention is not limited to the following embodiments. Furthermore, component elements in the following embodiments include component elements that are readily conceivable by a person skilled in the art or that are substantially equivalent.

### Circuit Configuration of Semiconductor Memory Device

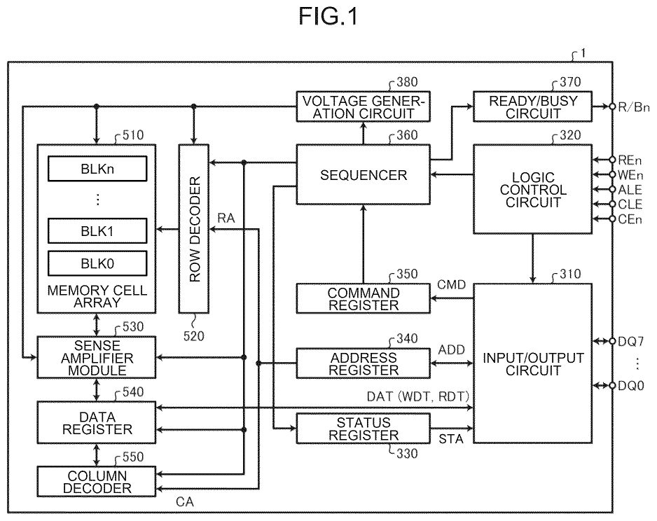

First, an example of a circuit configuration of a semiconductor memory device 1 according to an embodiment will be described with reference to FIGS. 1 to 6B.

### (Overall Configuration of Semiconductor Memory Device)

FIG. 1 is a block diagram of the semiconductor memory device 1 according to an embodiment. As illustrated in FIG. 1, the semiconductor memory device 1 includes an input/output circuit 310, a logic control circuit 320, a status register 330, an address register 340, a command register 350, a sequencer 360, a ready/busy circuit 370, a voltage generation circuit 380, a memory cell array 510, a row decoder 520, a sense amplifier module 530, a data register 540, and a column decoder 550.

The input/output circuit 310 controls input/output of a signal DQ with an external device such as a memory controller, which is not illustrated, controlling the semiconductor memory device 1. The input/output circuit 310 includes an input circuit and an output circuit which are not illustrated.

The input circuit receives data DAT, for example, write data WDT, address ADD, and command CMD from the external device, and transmits the data DAT to the data register 540, transmits the address ADD to the address register 340, and transmits the command CMD to the command register 350.

The output circuit transmits status information STA received from the status register 330, data DAT such as read data RDT received from the data register 540, and the address ADD received from the address register 340, to the external device.

The logic control circuit 320 receives, for example, a chip enable signal CEn, a command latch enable signal CLE, an address latch enable signal ALE, a write enable signal WEn, and a read enable signal REn, from the external device. In addition, the logic control circuit 320 controls the input/output circuit 310 and the sequencer 360 according to the received signals.

The status register 330 temporarily holds status information STA in, for example, a write operation, a read operation, and an erase operation for data, and notifies the external device of whether the operations have normally ended.

The address register 340 temporarily holds the address ADD received from the external device via the input/output circuit 310. In addition, the address register 340 transfers a row address RA to the row decoder 520 and transfers a column address CA to the column decoder 550.

The command register 350 temporarily stores the command CMD received from the external device via the input/output circuit 310 and transfers the command CMD to the sequencer 360.

The sequencer 360, a type of controller, controls the operation of the entire semiconductor memory device 1. More specifically, the sequencer 360 controls, for example, the status register 330, the ready/busy circuit 370, the voltage generation circuit 380, the row decoder 520, the sense amplifier module 530, the data register 540, the column decoder 550, and the like, according to the command CMD held by the command register 350, and executes the write operation, the read operation, the erase operation, and the like.

The ready/busy circuit 370 transmits a ready/busy signal R/Bn to the external device according to operating conditions of the sequencer 360.

The voltage generation circuit 380 generates voltages necessary for the write operation, the read operation, and the erase operation, according to the control of the sequencer 360, and supplies the generated voltages to, for example, the memory cell array 510, the row decoder 520, the sense amplifier module 530, and the like. The row decoder 520 and the sense amplifier module 530 apply the voltage supplied from the voltage generation circuit 380 to memory cells in the memory cell array 510.

The memory cell array 510 includes a plurality of blocks BLK (BLK0 to BLKn). The symbol n is an integer of 1 or more. Each of the blocks BLK is a set of a plurality of memory cells associated with bit lines and word lines, and is, for example, a data erase unit. Each of the memory cells is configured as, for example, a transistor to hold nonvolatile data.

The semiconductor memory device 1 including the memory cell configured as described above, is configured as, for example, a NAND nonvolatile memory.

The row decoder 520 decodes the row address RA. In addition, the row decoder 520 selects any block BLK on the basis of a result of the decoding. The row decoder 520 applies a necessary voltage to the block BLK.

During the read operation, the sense amplifier module 530 senses data read from the memory cell array 510. In addition, the sense amplifier module 530 transmits the read data RDT to the data register 540. During the write operation, the sense amplifier module 530 transmits the write data WDT to the memory cell array 510.

The data register 540 includes a plurality of latch circuits. Each of the latch circuits holds the write data WDT and the read data RDT. For example, in the write operation, the data register 540 temporarily holds the write data WDT received from the input/output circuit 310, and transmits the write data WDT to the sense amplifier module 530. In addition, for example, in the read operation, the data register 540 temporarily holds the read data RDT received from the sense amplifier module 530 and transmits the read data RDT to the input/output circuit 310.

The column decoder 550 decodes the column address CA during, for example, the write operation, the read operation, and the erase operation to select a latch circuit in the data register 540 according to the decoding result.

Note that a group of circuits arranged around the memory cell array 510 is also referred to as peripheral circuits. The peripheral circuits include at least the row decoder 520, the sense amplifier module 530, the data register 540, and the column decoder 550. The peripheral circuits may include the status register 330, the address register 340, the command register 350, and the sequencer 360, and may further include the input/output circuit 310, the logic control circuit 320, the ready/busy circuit 370, and the voltage generation circuit 380.

As described above, the semiconductor memory device 1 includes the memory cell array 510 that includes the plurality of memory cells and the peripheral circuits that operate the plurality of memory cells.

### (Circuit Configuration of Block)

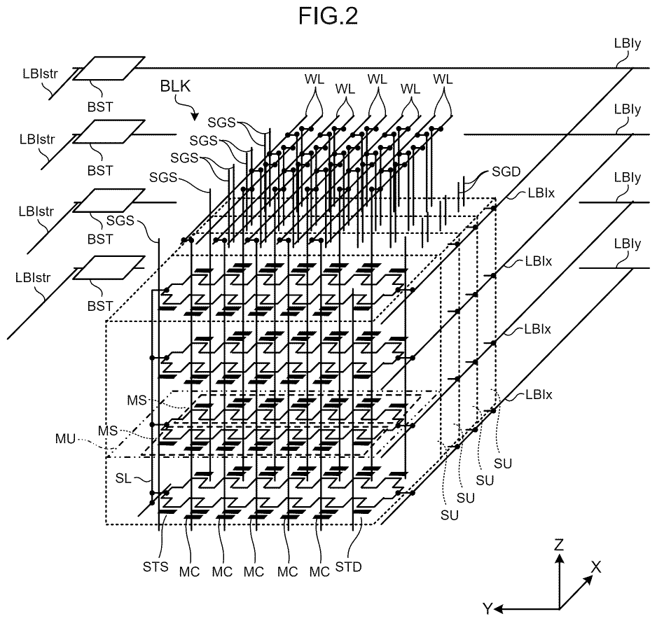

FIG. 2 is a schematic circuit diagram illustrating an exemplary configuration of a block BLK included in the semiconductor memory device 1 according to an embodiment. As will be described in detail later, the semiconductor memory device 1 of the embodiment is configured as, for example, a three-dimensional nonvolatile memory or the like. Accordingly, In FIG. 2, the configuration of memory cells MC and the like included in the block BLK is three-dimensionally illustrated.

The memory cell array 510 includes a plurality of the blocks BLK as described above. Each of the plurality of the blocks BLK includes a plurality of string units SU. In one block BLK, the plurality of string units SU are aligned in an X-direction.

In addition, as described later, the semiconductor memory device 1 of the embodiment has a stacked structure in which a plurality of layers are stacked in a Z-direction, and each of the plurality of string units SU includes a plurality of memory units MU provided corresponding to these layers. Each of the plurality of memory units MU includes two memory strings MS.

Each of the two memory strings MS has one end that is connected to a peripheral circuit such as the sense amplifier module 530 via common bit lines LBIx, LBIy, LBIstr, or the like. Each of the two memory strings MS has the other end that is connected to a peripheral circuit via a common source line SL.

A plurality of the bit lines LBIx corresponding to the one block BLK extend in the X-direction at positions corresponding to the plurality of memory units MU provided corresponding to the layers described above, on one side of the block BLK in a Y-direction. A plurality of the bit lines LBIy corresponding to the bit lines LBIx and connected to the bit lines LBIx extend in the Y-direction at positions in the Z-direction corresponding to the bit lines LBIx, on one side of the corresponding block BLK in the X-direction.

Note that the bit lines LBIy are each provided with a booster circuit BST which will be described in detail later.

A plurality of the bit lines LBIstr corresponding to the plurality of the bit lines LBIy corresponding to the one block BLK and connected to the bit lines LBIy extend in the X-direction at positions in the Z-direction corresponding to the bit lines LBIy, on the other side of the corresponding block BLK in the Y-direction.

These bit lines LBIstr corresponding to the one block BLK have extending portions that do not overlap each other in the Z-direction, and connection of contacts extending in the Z-direction which will be described later to these portions that do not overlap each other in the Z-direction enables electrical drawing of these bit lines LBIstr above the plurality of layers, for connection to the sense amplifier module 530.

Note that in connection between the plurality of the memory cells MC and the sense amplifier module 530, these bit lines LBIx, LBIy, and LBIstr are also referred to as local bit lines that are arranged on the side of the block BLK. These local bit lines are connected to global bit lines, which will be described later, arranged on the side of the sense amplifier module 530, whereby the plurality of the memory cells MC and the sense amplifier module 530 are electrically connected.

Each memory string MS includes a plurality of the memory cells MC and select transistors STD and STS that are connected in series between each of the bit lines LBIx and the source line SL. The select transistor STD, the plurality of the memory cells MC, and the select transistor STS extend in this order in the Y-direction. At this time, the select transistor STD connected to the bit line LBIx is a drain-side select transistor, and the select transistor STS connected to the source line SL is a source-side select transistor.

The memory cells MC are each, for example, a field effect transistor (FET) that includes a charge trap layer in a gate insulating layer. A threshold voltage of each memory cell MC changes according to a charge amount in the charge trap layer. One or a plurality of threshold voltages may be provided to enable the memory cell MC to store data of one bit or a plurality of bits. A word line WL is connected to each of gate electrodes of the plurality of the memory cells MC corresponding to one memory string MS. These word lines WL are commonly connected to all the memory units MU in the one block BLK.

More specifically, a word line WL extending in the Z-direction in the block BLK is commonly connected to a plurality of the memory cells MC located at the same arrangement positions in the memory strings MS, that is, at the same positions between the select transistors STD and STS, from among the plurality of the memory cells MC included in a plurality of memory units MU overlapping each other in the Z-direction. In addition, in each of the string units SU aligned in the X-direction, a plurality of the word lines WL connected to the plurality of the memory cells MC located at the same arrangement positions in the memory strings MS and extending in the Z-direction is connected together, for example, on an outer side of the block BLK in the Z-direction and extends in the X-direction.

The select transistors STD and STS are, for example, field effect transistors. The selection gate lines SGD and SGS are connected to gate electrodes of the select transistors STD and STS, respectively. Two selection gate lines SGD that correspond to the two memory strings MS included in the one memory unit MU and are drain-side selection gate lines are commonly connected to all the memory units MU in one string unit SU. Two selection gate lines SGS that correspond to the two memory strings MS included in the one memory unit MU and are source-side selection gate lines are commonly connected to all the memory units MU in one string unit SU.

More specifically, a selection gate line SGD extending in the Z-direction in the block BLK is commonly connected to a plurality of the select transistors STD included in the plurality of memory units MU overlapping each other in the Z-direction. Furthermore, a selection gate line SGS extending in the Z-direction in the block BLK is commonly connected to a plurality of the select transistors STS included in the plurality of memory units MU overlapping each other in the Z-direction.

Each of the word line WL and the selection gate lines SGD and SGS has one end that is connected to a peripheral circuit such as the row decoder 520.

Note that the select transistor STD, the plurality of the memory cells MC, and the select transistor STS that are included in the one memory string MS share a channel. In other words, the channel included in one memory string MS also extends in the Y-direction at a position corresponding to the plurality of layers included in the semiconductor memory device 1 of the embodiment.

### (Circuit Configuration and Operation of Sense Amplifier Module)

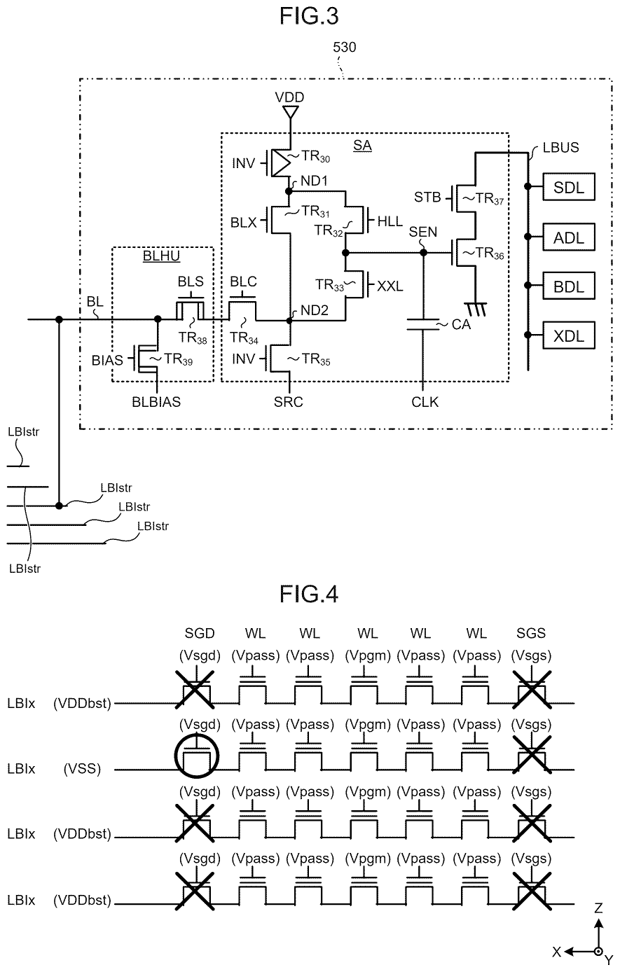

FIG. 3 is a circuit diagram illustrating an exemplary configuration of a sense amplifier circuit SA and latch circuits SDL, ADL, BDL, and XDL included in the semiconductor memory device 1 according to an embodiment. The sense amplifier module 530 described above includes a plurality of the sense amplifier circuits SA each of which is provided for each bit line BL.

The bit line BL illustrated in FIG. 3 corresponds to each of the global bit lines that connect the bit lines LBIstr described above, being some of the local bit lines, and the sense amplifier circuits SA, and is connected to a corresponding sense amplifier circuit SA via a bit line connection unit BLHU.

Note that in the example of FIG. 3, the individual bit lines LBIstr and the bit lines BL are connected one-to-one, but a plurality of bit lines LBIstr may be connected to one bit line BL. In order to miniaturize the semiconductor memory device 1, the plurality of the bit lines BL are arranged at a narrow pitch. The many-to-one connection between the bit lines LBIstr and the bit line BL enables reduction of the number of bit lines BL to increase the pitch. The booster circuit BST described above also functions as a switch circuit, and therefore, this configuration enables selection of a bit line LBIstr connected to a memory unit MU to be operated, from among the plurality of the bit lines LBIstr connected to the one bit line BL, for electrical connection with the sense amplifier circuits SA.

For example, in the read operation, each sense amplifier circuit SA senses data read through a corresponding bit line BL and determines whether the read data is “0” or “1”.

In addition, the data register 540 described above (see FIG. 1) includes a plurality of latch circuits SDL, ADL, BDL, and XDL corresponding to each of the plurality of the sense amplifier circuits SA. These latch circuits SDL, ADL, BDL, and XDL are also provided for each bit line BL. The sense amplifier circuit SA and the latch circuits SDL, ADL, BDL, and XDL are connected to a bus LBUS, enabling transmission and reception of data to and from each other via the bus LBUS.

The latch circuits SDL, ADL, BDL, and XDL temporarily hold data related to the corresponding bit line BL. The numbers of the latch circuits SDL, ADL, and BDL are designed on the basis of, for example, the number of bits of data that can be held by one memory cell MC.

The latch circuit XDL is connected to the input/output circuit 310 (see FIG. 1) of the semiconductor memory device 1, and is used for input/output of data between the sense amplifier circuit SA and the input/output circuit 310. Furthermore, the latch circuit XDL may also be used as, for example, a cache memory of the semiconductor memory device 1. For example, in the semiconductor memory device 1, even when the latch circuits SDL, ADL, and BDL are in use, the semiconductor memory device 1 is allowed to receive data from the outside, if the latch circuit XDL is available.

FIG. 3 illustrates one sense amplifier circuit SA in the sense amplifier module 530, and one set of latch circuits SDL, ADL, BDL, and XDL in the data register 540.

As illustrated in FIG. 3, the sense amplifier circuit SA includes transistors TR₃₀ to TR₃₇ and a capacitor CA, and the bit line connection unit BLHU includes transistors TR₃₈ and TR₃₉.

The transistor TR₃₀ is a low-voltage P-channel metal-oxide-semiconductor (MOS) FET. Each of the transistors TR₃₁ to TR₃₇ is a low-voltage N-channel MOSFET. Each of the transistors TR₃₈ and TR₃₉ is a high-voltage N-channel MOSFET.

A low-voltage CMOS transistor including a low-voltage P-channel MOSFET and the low-voltage N-channel MOSFET is a transistor to which a relatively low voltage is applied, and is also referred to as a lower voltage (low voltage: LV, very low voltage: VLV) MOS transistor.

A high-voltage CMOS transistor including the high-voltage N-channel MOSFET is a transistor to which a relatively high voltage is applied, and is also called a high voltage (HV) MOS transistor.

The transistor TR₃₀ has a source that is connected to a power line. The transistor TR₃₀ has a drain that is connected to a node ND1. The transistor TR₃₀ has a gate that is connected to a node INV. The node INV is, for example, a node included in the latch circuit SDL. The transistor TR₃₁ has a drain that is connected to the node ND1. The transistor TR₃₁ has a source that is connected to a node ND2. A control signal BLX is input to a gate of the transistor TR₃₁.

The transistor TR₃₂ has a drain that is connected to the node ND1. The transistor TR₃₂ has a source that is connected to a node SEN. A control signal HLL is input to a gate of the transistor TR₃₂. The transistor TR₃₃ has a drain that is connected to the node SEN. The transistor TR₃₃ has a source that is connected to the node ND2. A control signal XXL is input to a gate of the transistor TR₃₃.

The transistor TR₃₄ has a drain that is connected to the node ND2. A control signal BLC is input to a gate of the transistor TR₃₄. The transistor TR₃₅ has a drain that is connected to the node ND2. The transistor TR₃₅ has a source that is connected to a node SRC. The transistor TR₃₅ has a gate that is connected to, for example, the node INV in the latch circuit SDL.

The transistor TR₃₆ has a source that is grounded. The transistor TR₃₆ has a gate that is connected to the node SEN. The transistor TR₃₇ has a drain that is connected to the bus LBUS. The transistor TR₃₇ has a source that is connected to a drain of the transistor TR₃₆. A control signal STB is input to a gate of the transistor TR₃₇.

The capacitor CA has one electrode that is connected to the node SEN. A clock CLK is input to the other electrode of the capacitor CA.

The transistor TR₃₈ has a drain that is connected to a source of the transistor TR₃₄. The transistor TR₃₈ has a source that is connected to the bit line BL. A control signal BLS is input to a gate of the transistor TR₃₈. The transistor TR₃₉ has a drain that is connected to a node BLBIAS. The transistor TR₃₉ has a source that is connected to the bit line BL. A control signal BIAS is input to a gate of the transistor TR₃₉.

In the sense amplifier circuit SA, the bit line connection unit BLHU, and the latch circuits SDL, ADL, BDL, and XDL that have the above configurations, for example, a power supply voltage VDD is applied to the power line connected to the source of the transistor TR₃₀. The power supply voltage VDD is, for example, a maximum voltage that the sense amplifier module 530 can output. For example, a reference voltage VSS is applied to the node SRC. The reference voltage VSS is, for example, 0 V.

For example, an erase voltage VERA is applied to the node BLBIAS. In the node INV included in the latch circuit SDL, voltage changes on the basis of the data held by the latch circuit SDL.

The control signals BLX, HLL, XXL, BLC, STB, BLS, and BIAS and the clock CLK are generated by, for example, the sequencer 360 (see FIG. 1). In the read operation, the sense amplifier circuit SA determines the data read to the bit line BL on the basis of, for example, the timing at which the control signal STB is enabled.

Next, operation of the sense amplifier circuit SA having the above configuration will be briefly described.

In an example of writing data to the memory cell MC, when charge is injected into the memory cell MC to raise the threshold, an “H” level (“0” data) is stored in the node INV of the latch circuit SDL. As a result, the transistor TR₃₅ is turned on, and the reference voltage VSS is applied to the bit line BL connected to a memory cell MC to be written.

In another example of the case of writing data to the memory cell MC, when charge is not injected into the memory cell MC and the threshold is not changed, an “L” level (“1” data) is stored in the node INV of the latch circuit SDL. As a result, the transistor TR₃₀ is turned on, and the power supply voltage VDD is applied to the bit line BL connected to the memory cell MC to be written.

In reading, the node INV is set to the “L” level, the transistor TR₃₀ is turned on, and the bit line BL is precharged. In addition, the transistor TR₃₂ is also turned on, and the node SEN is charged to a predetermined potential.

Thereafter, the transistor TR₃₅ is turned off, the signal XXL is set to the “H” level, and the transistor TR₃₆ is turned on. Accordingly, when the corresponding memory cell MC is turned on, the potential of the node SEN decreases, and the transistor TR₃₆ is turned off. On the other hand, when the corresponding memory cell MC is turned off, the potential of the node SEN maintains the “H” level, and the transistor TR₃₆ is turned on.

In addition, the transistor TR₃₇ is turned on by the signal STB, and a potential corresponding to on/off of the transistor TR₃₆ is read to the bus LBUS and held in any of the latch circuits SDL, ADL, BDL, and XDL.

Note that circuit configurations of the sense amplifier circuit SA and the latch circuits SDL, ADL, BDL, and XDL illustrated in FIG. 3 are an example, and the sense amplifier circuit SA and the latch circuits SDL, ADL, BDL, and XDL may adopt various configurations in addition to the above configurations.

Here, in one string unit SU, the write operation to the memory cells MC is performed for each word line WL. Therefore, while the reference voltage VSS is applied to a bit line BL connected to, for example, a memory cell MC to be written with “0” data, from among a plurality of the memory cells MC connected to the common word lines WL, as described above, write suppression voltage is applied to bit lines BL connected to the memory strings MS including memory cells MC not to be written, suppressing writing of data to these memory cells MC not to be written. Details of the operation as described above will be described with reference to FIG. 4.

FIG. 4 is a schematic diagram illustrating the write operation of the semiconductor memory device 1 according to an embodiment.

FIG. 4 illustrates memory strings MS included in one string unit SU. However, in order to avoid complication of the drawing, only one of the two memory strings MS of memory units MU included in the string unit SU is illustrated.

In addition, in the example of FIG. 4, it is assumed that a memory cell MC that is included in a memory string MS connected to a bit line BL at the second to the upper layer and that is positioned at the center between select transistors STD and STS at both ends of the memory string MS, that is, at the third place to the left side of the drawing from among five memory cells MC included in the memory string MS is the memory cell MC to be written.

As illustrated in FIG. 4, in the write operation, the reference voltage VSS is applied to the memory string MS including the memory cell MC to be written, from the bit line BL via the bit lines LBIstr, LBIy, LBIx, and the like. In addition, write suppression voltage VDDbst is applied to the other memory strings MS, from the bit line BL via the bit lines LBIstr, LBIy, LBIx, and the like. The write suppression voltage VDDbst has a voltage value obtained by boosting the power supply voltage VDD supplied from the bit line BL by the booster circuit BST (see FIG. 2) provided for a corresponding bit line LBIy.

In addition, in the write operation, voltage Vsgd and voltage Vsgs are respectively applied to the select transistors STD and STS in the string unit SU including the memory cell MC to be written, from the selection gate lines SGD and SGS connected to the select transistors STD and STS. The voltage Vsgd is a voltage at which the select transistor STD is turned on when voltage applied from the bit line BL is approximately the reference voltage VSS. The voltage Vsgs is a voltage at which the select transistor STS is turned off regardless of a threshold voltage of the select transistor STS. Accordingly, the select transistors STS belonging to the memory strings MS in the string unit SU always remain turned off, and while the memory strings MS have a low channel potential, all the select transistors STD belonging to the memory strings MS in the string unit SU are turned on.

Thereafter, when the channel potential of the memory strings MS including the memory cells MC not to be written increases due to the write suppression voltage VDDbst higher than the reference voltage VSS, the select transistors STD belonging to these memory strings MS are cut off. Meanwhile, the channel potential of the memory string MS including the memory cell MC to be written is kept to the reference voltage VSS, and therefore, the select transistor STD is kept on.

Furthermore, in the write operation, a program voltage Vpgm is applied to a word line WL connected to the memory cell MC to be written. The program voltage Vpgm is a voltage that can cause the charge trap layer of the memory cell MC to store charge. In addition, transfer voltage Vpass is applied to the word lines WL connected to the other memory cells MC. The transfer voltage Vpass is a voltage at which the memory cell MC is turned on regardless of the threshold voltage of the memory cell MC.

As described above, in the memory cell MC to be written, charge (electrons) is injected into the charge trap layer from the channel due to a potential difference between the channel potential and the program voltage Vpgm applied from the word line WL, and the threshold voltage shifts in a positive direction. Therefore, for example, “0” data is written to the memory cell MC to be written.

Meanwhile, in the memory strings MS to which the memory cells MC not to be written belong, the select transistors STD are cut off. Therefore, the channel of these memory cells MC is electrically floated, and is coupled with the word line WL to which the program voltage Vpgm is applied and the word lines WL to which the transfer voltage Vpass is applied, and voltage of the channel is raised to boost voltage Vboost. Accordingly, the potential difference between the channel potential and the program voltage Vpgm applied from the word line WL decreases, preventing charge (electron) injection from the channel into the charge trap layers. This configuration suppresses writing of data to the memory cells MC not to be written.

At this time, unless the potential difference between the channel and the program voltage Vpgm is sufficiently small, each of the memory cells MC not to be written is susceptible to program disturb. The program disturb is a phenomenon in which the threshold voltage shifts in the positive direction and a weak program condition is caused even in the memory cells MC not to be written. As described above, applying the write suppression voltage VDDbst to each of the memory strings MS including the memory cells MC not to be written to increase the channel potential in advance enables rising of the value of the boost voltage Vboost in the channel and reduction of the potential difference between the channel and the program voltage Vpgm.

In the semiconductor memory device 1 of the embodiment, the power supply voltage VDD supplied from the bit line BL is further boosted by the booster circuit BST to obtain the write suppression voltage VDDbst. This configuration enables sufficient reduction of the potential difference between the channel and the program voltage Vpgm to suppress the program disturb in the memory cells MC not to be written.

### (Circuit Configuration and Operation of Booster Circuit)

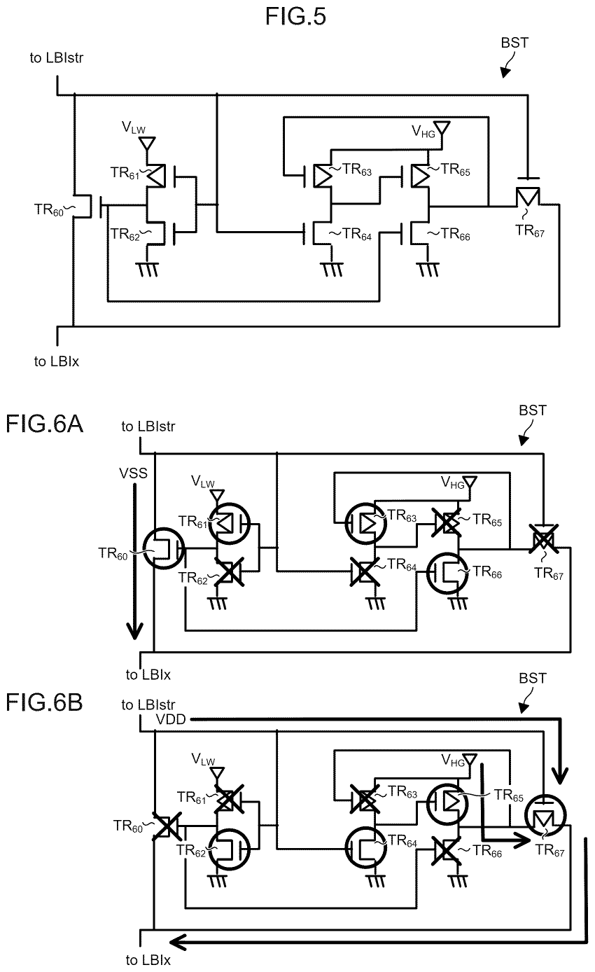

FIG. 5 is a circuit diagram illustrating an exemplary configuration of the booster circuit BST included in the semiconductor memory device 1 according to an embodiment. As described above, the booster circuit BST is provided for each of the plurality of the bit lines LBIy. More specifically, the booster circuit BST is inserted in the middle of the corresponding bit line LBIy.

As illustrated in FIG. 5, each booster circuit BST includes transistors TR₆₀ to TR₆₇. Each of the transistors TR₆₀, TR₆₂, TR₆₄, and TR₆₆ is a low-voltage N-channel MOSFET. Each of the transistors TR₆₁, TR₆₃, TR₆₅, and TR₆₇ is a low-voltage P-channel MOSFET.

The transistor TR₆₀ is inserted in the middle of the bit line LBIy, has a drain that is connected to a side of the bit line LBIy leading to the bit line LBIstr, and has a source that is connected to a side of the bit line LBIy leading to the bit line LBIx.

The transistor TR₆₁ has a source that is connected to a power line. The transistor TR₆₂ has a drain that is connected to a drain of the transistor TR₆₁. Furthermore, the drains of the transistors TR₆₁ and TR₆₂ are connected to a gate of the transistor TR₆₀. The transistor TR₆₂ has a source that is grounded. The gates of the transistors TR₆₁ and TR₆₂ are connected to the side of the bit line LBIy leading to the bit line LBIstr.

The transistor TR₆₃ has a source that is connected to a power line. The transistor TR₆₄ has a drain that is connected to a drain of the transistor TR₆₃. The transistor TR₆₄ has a source that is grounded. The transistor TR₆₄ has a gate that is connected to the side of the bit line LBIy leading to the bit line LBIstr.

The transistor TR₆₅ has a source that is connected to the power line. The transistor TR₆₅ has a gate that is connected to the drains of the transistors TR₆₃ and TR₆₄. The transistor TR₆₆ has a drain that is connected to a drain of the transistor TR₆₅. The drains of the transistors TR₆₅ and TR₆₆ are connected to a gate of the transistor TR₆₃. The transistor TR₆₆ has a source that is grounded. The transistor TR₆₆ has a gate that is connected to the drains of the transistors TR₆₁ and TR₆₂.

The transistor TR₆₇ has a source that is connected to the drains of the transistors TR₆₅ and TR₆₆. The transistor TR₆₇ has a drain that is connected to the side of the bit line LBIy leading to the bit line LBIx. The transistor TR₆₇ has a gate that is connected to the side of the bit line LBIy leading to the bit line LBIstr.

In the booster circuit BST having the above configuration, for example, a low-level voltage V_{LW} is applied to the power line connected to the source of the transistor TR₆₁. The voltage V_{LW} is a voltage at which the transistors TR₆₀, TR₆₆ and the like which are the low-voltage N-channel MOSFETs are turned on. For example, a high-level voltage V_{HG} is applied to the power line connected to the sources of the transistors TR₆₃ and TR₆₅. The voltage V_{HG} is a voltage higher than the power supply voltage VDD, and may be substantially equal to the write suppression voltage VDDbst applied to the memory strings MS including the memory cells MC not to be written.

Furthermore, the transistors TR₆₁ and TR₆₂, from among the transistors TR₆₀ to TR₆₇ included in the booster circuit BST, function as an inverter. In addition, the transistors TR₆₃ to TR₆₆ function as a level shifter for voltage level conversion.

Next, operations of the booster circuit BST having the above configuration will be described with reference to FIGS. 6A and 6B.

FIGS. 6A and 6B are schematic diagrams each illustrating an operation of the booster circuit BST included in the semiconductor memory device 1 according to an embodiment. More specifically, FIG. 6A illustrates an operation example of the booster circuit BST provided for the bit line LBIy connected to the memory string MS including the memory cell MC to be written. FIG. 6B illustrates an operation example of the booster circuit BST provided for a bit line LBIy connected to a memory string MS including the memory cells MC not to be written.

As illustrated in FIG. 6A, for example, the reference voltage VSS is supplied from the sense amplifier circuit SA to the bit line LBIy connected to the memory string MS including the memory cell MC to be written. The reference voltage VSS is also applied to the gates of the transistors TR₆₁, TR₆₂, TR₆₄, and TR₆₇. The reference voltage VSS is a voltage at which the transistors TR₆₁ and TR₆₇ being the low-voltage P-channel MOSFETs are turned on, and is a voltage at which the transistors TR₆₂ and TR₆₄ being the low-voltage N-channel MOSFETs are not turned on.

Furthermore, the low-level voltage V_{LW} is applied to the power line connected to the source of the transistor TR₆₁, and the high-level voltage V_{HG} is applied to the power line connected to the sources of the transistors TR₆₃ and TR₆₅.

Therefore, the transistor TR₆₁ is turned on, and the voltage V_{LW} is applied from the source of the transistor TR₆₁ to the gate of the transistor TR₆₀. Accordingly, the transistor TR₆₀ is turned on, and the voltage VSS supplied from the sense amplifier circuit SA to the bit line LBIy is transferred to the memory string MS connected to the bit line LBIy.

Note that the voltage VSS supplied to the bit line LBIy does not reach threshold voltages of the transistors TR₆₂ and TR₆₄, and these transistors TR₆₂ and TR₆₄ remain turned off.

Furthermore, the voltage V_{LW} from the source of the transistor TR₆₁ is also applied to the gate of the transistor TR₆₆, and the transistor TR₆₆ is also turned on. Therefore, a ground voltage is applied to the gate of the transistor TR₆₃ via the transistor TR₆₆. Therefore, the transistor TR₆₃ is turned on, and the voltage V_{HG} is applied to the gate of the transistor TR₆₅ via the transistor TR₆₃. Accordingly, the transistor TR₆₅ is turned off, and the voltage V_{HG} from the transistor TR₆₃ is not supplied to the source of the transistor TR₆₇.

Furthermore, the voltage VSS from the bit line LBIy is applied to the gate of the transistor TR₆₇, but the source of the transistor TR₆₇ is grounded via the transistor TR₆₆, and the transistor TR₆₇ remains turned off.

As illustrated in FIG. 6B, for example, the power supply voltage VDD is supplied from the sense amplifier circuit SA to the bit line LBIy connected to the memory string MS including the memory cells MC not to be written. The power supply voltage VDD is also applied to the gates of the transistors TR₆₁, TR₆₂, TR₆₄, and TR₆₇. Furthermore, the low-level voltage V_{LW} is applied to the power line connected to the source of the transistor TR₆₁, and the high-level voltage V_{HG} is applied to the power line connected to the sources of the transistors TR₆₃ and TR₆₅.

Therefore, the transistors TR₆₂ and TR₆₄ are turned on, and the ground voltage is applied to the gate of the transistor TR₆₅ via the transistor TR₆₄. Therefore, the transistor TR₆₅ is turned on, and the voltage V_{HG} is supplied from the source of the transistor TR₆₅ to the source of the transistor TR₆₇.

Furthermore, as described above, the power supply voltage VDD from the bit line LBIy is applied to the gate of the transistor TR₆₇. However, the transistor TR₆₇ is turned on due to a potential difference between the power supply voltage VDD and the high-level voltage V_{HG} applied to the source of the transistor TR₆₇, and the voltage V_{HG} supplied from the source of the transistor TR₆₅ is transferred to the memory string MS connected to the bit line LBIy via the transistor TR₆₇.

As described above, the voltage V_{HG} is, for example, substantially equal to the write suppression voltage VDDbst, and when the transistor TR₆₇ is turned on, the power supply voltage VDD supplied from the sense amplifier circuit SA to the bit line LBIy is boosted to the write suppression voltage VDDbst and applied to the memory string MS connected to the bit line LBIy.

Note that the voltage V_{HG} from the source of the transistor TR₆₅ is also applied to the gate of the transistor TR₆₃, and therefore, the transistor TR₆₃ is turned off, the voltage V_{HG} from the source of the transistor TR₆₃ is not applied to the gate of the transistor TR₆₅, and the transistor TR₆₅ is kept on.

In addition, the transistor TR₆₁ is turned off, and therefore, the voltage V_{LW} from the source of the transistor TR₆₁ is not applied to the gates of the transistors TR₆₀ and TR₆₆, and these transistors TR₆₀ and TR₆₆ remain turned off. Therefore, the voltage VDD supplied from the sense amplifier circuit SA to the bit line LBIy is temporarily interrupted by the transistor TR₆₀, and is not directly transferred to the memory string MS connected to the bit line LBIy.

Note that the circuit configuration of the booster circuit BST illustrated in FIGS. 5 to 6B is an example, and the booster circuit BST may adopt various configurations in addition to the above configuration.

### Physical Configuration of Semiconductor Memory Device

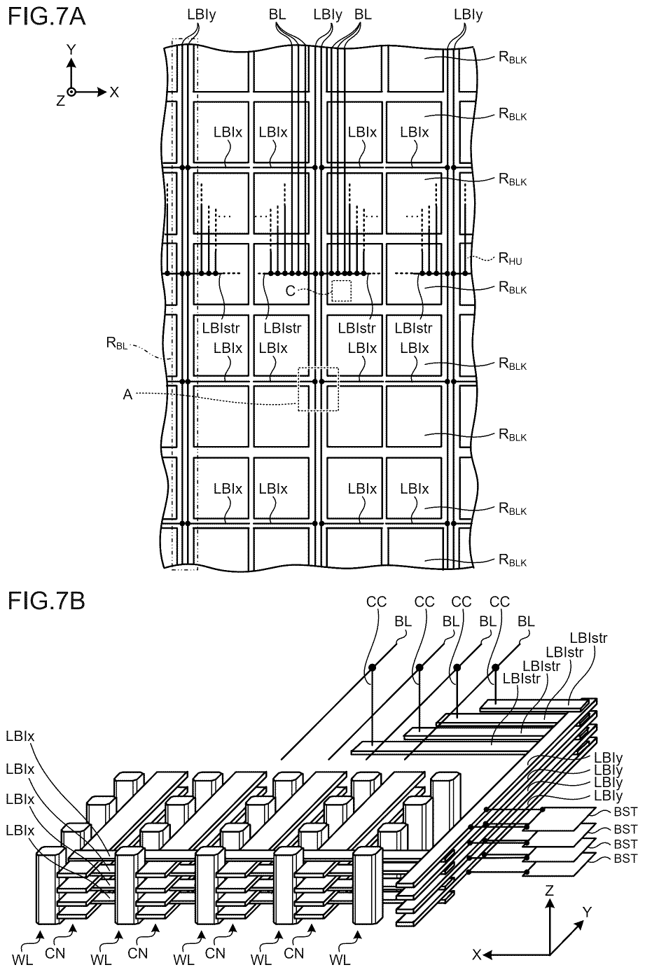

Next, an exemplary physical configuration of the semiconductor memory device 1 according to an embodiment will be described with reference to FIGS. 7A to 12B.

### (Configuration Example of Block Region)

First, a configuration example of a block region R_{BLK} included in the semiconductor memory device 1 will be described with reference to FIGS. 7A to 9.

FIGS. 7A and 7B are schematic diagrams each illustrating an exemplary configuration of a partial area of the semiconductor memory device 1 according to an embodiment. More specifically, FIG. 7A is a plan view illustrating a configuration example of regions each including the block region R_{BLK}, and FIG. 7B is a schematic perspective view illustrating a connection relationship between the block regions R_{BLK} and the bit lines LBIx, LBIy, LBIstr, and BL. Note that FIG. 7A illustrates a plane of one of the plurality of layers included in the semiconductor memory device 1.

As illustrated in FIG. 7A, the semiconductor memory device 1 includes a plurality of the block regions R_{BLK}, a plurality of hook-up regions R_{HU}, and a plurality of bit line regions R_{BL}.

Each of the block regions R_{BLK} corresponds to a physical configuration of the block BLK described above (see FIG. 2 and the like), and is arranged in a matrix in the X-direction and the Y-direction. The hook-up regions R_{HU} are provided between the plurality of the block regions R_{BLK} aligned in the Y-direction. The hook-up regions R_{HU} are arranged side by side in the X-direction, and are adjacent to the block regions R_{BLK} in the Y-direction. The bit line regions R_{BL} are provided between the plurality of the block regions R_{BLK} and the hook-up regions R_{HU}. The bit line regions R_{BL} extend in the Y-direction at positions aligned with the plurality of the block regions R_{BLK} and the hook-up regions R_{HU} in the X-direction.

Furthermore, in the example of FIG. 7A, bit lines LBIx each extend in a direction along the X-direction, between two block regions R_{BLK} aligned in the Y-direction. In these two block regions R_{BLK}, a plurality of channel layers CN illustrated in FIG. 7B is connected to each of the bit lines LBIx.

As illustrated in FIG. 7B and as described above, in the block regions R_{BLK}, the plurality of channel layers CN extending in the Y-direction is provided in multiple stages corresponding to the plurality of layers, and the channel layers CN stacked in the multiple stages are arranged side by side in the X-direction. Each of the channel layers CN corresponds to a physical configuration of the channel provided in common between the plurality of the memory cells MC and the select transistors STD and STS which are included in the memory string MS described above.

Between the channel layers CN aligned in the X-direction, a plurality of the word lines WL extending in the Z-direction is arranged in an extending direction of the channel layers CN so as to be spaced apart from each other in the Y-direction. The channel layers CN aligned in the X-direction corresponding to each layer are commonly connected to one bit line LBIx.

As illustrated in FIG. 7A, each of the bit line regions R_{BL} is provided with bit lines LBIy extending in the Y-direction. A plurality of the bit lines LBIx extending in the X-direction across one bit line LBIy between two block regions R_{BLK} is commonly connected to this bit line LBIy. Furthermore, in each of the hook-up regions R_{HU}, the bit line LBIy is connected to the bit line BL via the bit line LBIstr, and is electrically connected to a corresponding sense amplifier circuit SA.

As illustrated in FIG. 7B, the plurality of the bit lines LBIstr are arranged, for example, stepwise and have portions not overlapping each other in the Z-direction, and the bit lines LBIy stacked in multiple stages in different layers are each connected to the bit line LBIstr in the same layer. In addition, stepped portions of these bit lines LBIstr are each provided with a contact CC, and the contact portion CC is connected to each of a plurality of the bit lines BL extending above the block region R_{BLK} in the Y-direction.

However, as described above, the bit line BL and the bit lines LBIstr may have the one-to-many connection.

In addition, in the block region R_{BLK}, the booster circuits BST are provided in the middle of each of the plurality of the bit lines LBIy that is connected to the plurality of the bit lines LBIx connected to the plurality of channel layers CN stacked in multiple stages and that extends in the Y-direction on one side in the X-direction in the block region R_{BLK}. In other words, a plurality of the booster circuits BST is arranged to be stacked in multiple stages together with the plurality of the bit lines LBIy, in the bit line region R_{BL} aligned in the X-direction with the corresponding block region R_{BLK}.

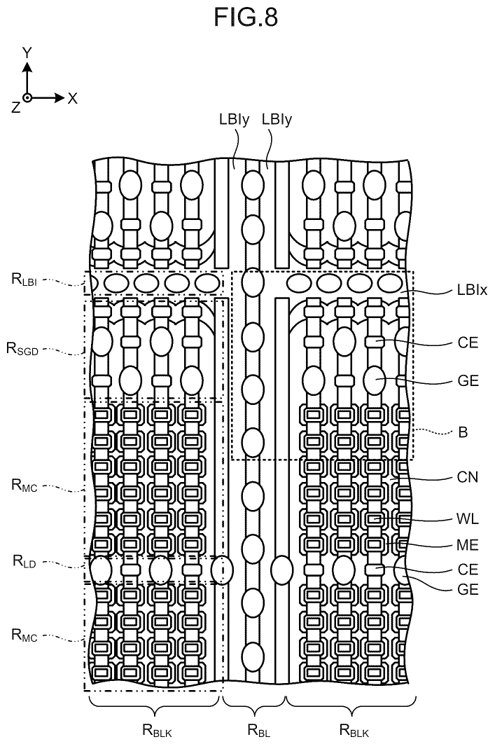

FIG. 8 is a plan view illustrating an exemplary configuration of a partial area of the semiconductor memory device 1 according to an embodiment. More specifically, FIG. 8 is an enlarged plan view of an area A illustrated in FIG. 7A described above.

As illustrated in FIG. 8, the block region R_{BLK} is provided with a plurality of memory cell regions R_{MC} aligned in the Y-direction, a ladder region R_{LD} provided between two memory cell regions R_{MC} adjacent in the Y-direction, and a select transistor region R_{SGD} arranged at an end of each block region R_{BLK} in the Y-direction. In addition, a bit line region R_{LBI} is provided between two block regions R_{BLK} aligned in the Y-direction, and a bit line region R_{BL} is provided between two block regions R_{BLK} aligned in the X-direction.

As described above, a plurality of channel layers CN extending in the Y-direction is arranged in each of the memory cell regions R_{MC}, and is connected to a plurality of the word lines WL extending in the Z-direction through a plurality of layers. Each of the channel layers CN is, for example, a semiconductor layer or the like, and functions as the channel of the memory cells MC in the memory cell region R_{MC}. The plurality of channel layers CN also extend to the ladder region R_{LD} and the select transistor region R_{SGD}.

In the ladder region R_{LD} and the select transistor region R_{SGD}, a plurality of contact electrodes CE extending in the Z-direction through the plurality of layers and a plurality of gate electrodes GE are arranged to be connected to the channel layers CN. The plurality of contact electrodes CE forms hole channels in the channel layer CN which is the semiconductor layer or the like, and supplies voltage to the hole channels formed in the channel layer CN. The ladder region R_{LD} including the plurality of contact electrodes CE and the gate electrodes GE functions as a relay circuit that transfers voltage between the channel layers CN extending in the Y-direction. In the select transistor region R_{SGD}, each of the gate electrode GE functions as the selection gate line SGD, and the channel layer CN functions as the channel for the select transistor STD.

In the bit line region R_{LBI}, the bit line LBIx that is a conductive layer such as a titanium nitride layer extends in the X-direction. The bit lines LBIy arranged in the bit line region R_{BL} and extending between the two block regions R_{BLK} aligned in the X-direction, in the Y-direction are also the conductive layer such as the titanium nitride layer.

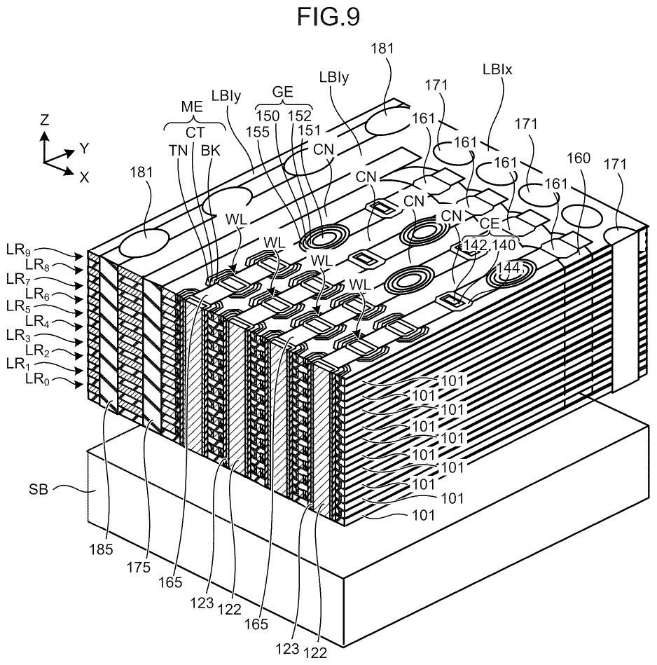

FIG. 9 is a perspective cross-sectional view illustrating an exemplary configuration including a block region R_{BLK} of the semiconductor memory device 1 according to an embodiment. More specifically, FIG. 9 is a perspective cross-sectional view including the portion of layers LR of an area B illustrated in FIG. 8 described above.

As illustrated in FIG. 9, the semiconductor memory device 1 includes a plurality of the layers LR (LR₀, LR₁, LR₂, . . . LR₉, . . . ) that is stacked in the Z-direction on a semiconductor substrate SB with an insulating layer 101 interposed therebetween. The semiconductor substrate SB is a silicon substrate containing a P-type impurity such as boron. The insulating layer 101 is, for example, a silicon oxide layer or the like.

Note that as will be described later, the plurality of the layers LR is a layer that includes various configurations such as the channel layer CN, the bit lines LBIx and LBIy, and the like and that is arranged in insulating layers such as a silicon nitride layer stacked with the insulating layers 101 interposed therebetween, and the layers LR are substantial portions of the semiconductor memory device 1 including the memory cells MC and the like. Hereinafter, a plurality of the layers LR with the insulating layers 101 interposed therebetween, or a structure in which the insulating layers 101 such as the silicon oxide layers and a plurality of insulating layers such as silicon nitride layers are stacked is also referred to as a stacked body.

Each of the plurality of the layers LR is provided with a plurality of channel layers CN spaced apart from each other in the X-direction and extending in the Y-direction. The channel layer CN is, for example, a semiconductor layer such as a non-doped polysilicon layer. Insulating layers 165 such as a silicon oxide layer extending in the Z-direction through a plurality of the layers LR and insulating layers 101 are arranged, between the channel layers CN aligned in the X-direction. In addition, a plurality of the word lines WL, gate electrodes GE, and contact electrodes CE extend in the Z-direction through the plurality of the layers LR and insulating layers 101, at positions overlapping with the insulating layers 165 in the Z-direction.

Each of the plurality of the word lines WL includes a conductive layer 122 that serves as a core material of the word line WL and a barrier metal layer 123 that covers a side wall of the conductive layer 122. The conductive layer 122 is, for example, a tungsten layer or the like, and the barrier metal layer 123 is, for example, a titanium nitride layer or the like.

In addition, a memory layer ME that covers a side wall of the barrier metal layer 123 is provided in the plurality of the layers LR. The memory layer ME has a stacked structure in which a block insulating layer BK, a charge trap layer CT, and a tunnel insulating layer TN are laminated in this order from the side of the barrier metal layer 123, and functions as the gate insulating layer for the memory cell MC having the channel layer CN as the channel. Each of the plurality of the word lines WL is connected to the channel layer CN via the memory layer ME.

The tunnel insulating layer TN is a silicon oxide layer or the like, and charges (electrons) in the channel layer CN are injected and held in the charge trap layer CT by the tunneling effect of the tunnel insulating layer TN, and data is written to the memory cell MC.

The charge trap layer CT is, for example, a polysilicon layer or the like, and holds charges injected from the channel layer CN to store data. The polysilicon layer of the charge trap layer CT may contain an N-type impurity such as phosphorus or a P-type impurity such as boron, or may not contain these impurities.

The block insulating layer BK is, for example, a silicon oxide layer or the like. The block insulating layer BK may include an insulating metal oxide layer such as an aluminum oxide layer or a hafnium oxide layer, in addition to the silicon oxide layer.

Each of the plurality of gate electrodes GE includes a conductive layer 152 that covers a side wall of an insulating layer 151 serving as a core material of the gate electrode GE, and a semiconductor layer 150 covering a side wall of the conductive layer 152. The insulating layer 151 is, for example, a silicon oxide layer or the like, the conductive layer 152 is, for example, a titanium nitride layer or the like, and the semiconductor layer 150 is, for example, a polysilicon layer containing an N-type impurity such as phosphorus or the like.

In addition, an insulating layer 155 such as a silicon oxide layer that covers a side wall of the semiconductor layer 150 is provided further outside the semiconductor layer 150.

As described above, in the select transistor region R_{SGD}, the gate electrode GE functions as the selection gate line SGD, the channel layer CN connected to the gate electrode GE via the insulating layer 155 functions as the channel for the select transistor STD, and the insulating layer 155 functions as a gate insulating layer for the select transistor STD.

Each of the plurality of contact electrodes CE includes a conductive layer 142 that serves as a core material of the contact electrode CE, and a semiconductor layer 140 that covers a side wall of the conductive layer 142. On the outside of each of the contact electrodes CE, a semiconductor layer 144 may be further provided that covers a side wall of the semiconductor layer 140 The conductive layer 142 is, for example, a titanium nitride layer or the like, the semiconductor layer 140 is, for example, a polysilicon layer or the like containing a P-type impurity such as boron, and the semiconductor layer 144 is, for example, a non-doped polysilicon layer or the like. However, the contact electrode CE may not include the semiconductor layer 144.

In the select transistor region R_{SGD}, a plurality of semiconductor layers 160 each connected to one end of the plurality of channel layers CN in the Y-direction is provided in each of the plurality of the layers LR. The semiconductor layer 160 is, for example, a polysilicon layer or the like containing an N-type impurity such as phosphorus. The insulating layers 165 described above are also arranged between the semiconductor layers 160 aligned in the X-direction, and at positions overlapping with the insulating layers 165 in the Z-direction, insulating layers 161 extend in the Z-direction through the plurality of the layers LR and insulating layers 101.

Furthermore, in the bit line region R_{LBI}, a plurality of insulating layers 171 extending in the Z-direction through the plurality of the layers LR and insulating layers 101 is arranged side by side in the X-direction along the bit line LBIx. The insulating layers 171 are each, for example, a silicon oxide layer or the like.

Furthermore, in the bit line region R_{BL}, each of the plurality of the layers LR is provided with a plurality of the bit lines LBIy spaced apart from each other in the X-direction and extending in the Y-direction. An insulating layer 185 such as a silicon oxide layer extending in the Z-direction through a plurality of the layers LR and insulating layers 101 is arranged, between these bit lines LBIy aligned in the X-direction. In addition, at positions overlapping the insulating layer 185 in the Z-direction, a plurality of insulating layers 181 extend in the Z-direction through the plurality of the layers LR and insulating layers 101. The insulating layers 181 are each, for example, a silicon oxide layer or the like.

In addition, an insulating layer 175 such as a silicon oxide layer is arranged that extends in the Z-direction through the plurality of the layers LR and insulating layers 101 to separate the bit line region R_{BL} and the block region R_{BLK}.

### (Configuration Example of Hook-Up Region)

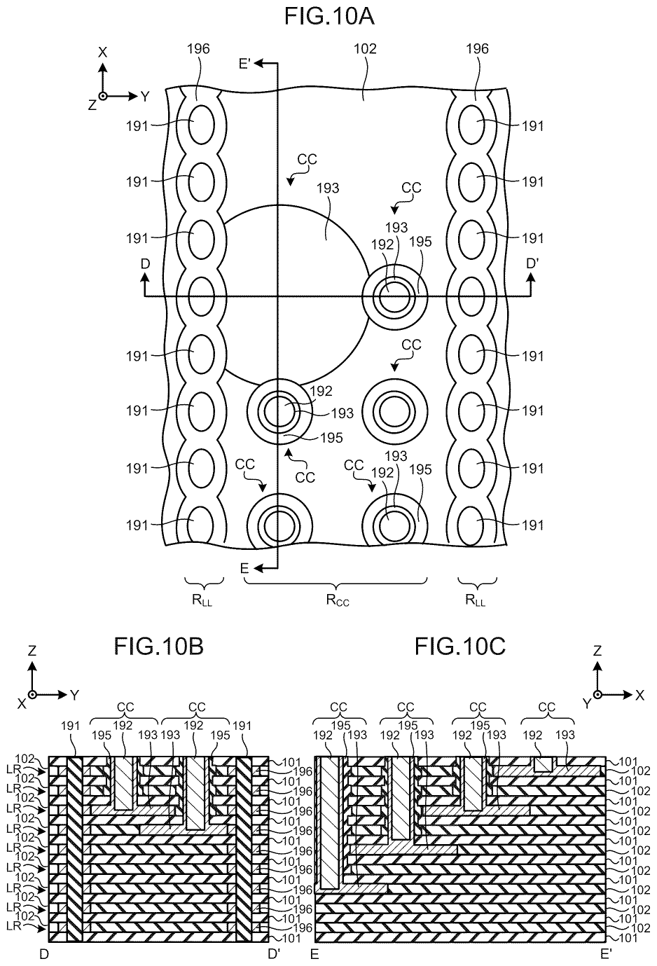

Next, a configuration example of the hook-up region R_{HU} included in the semiconductor memory device 1 will be described with reference to FIGS. 10A to 10C.

FIGS. 10A to 10C are schematic diagrams each illustrating an exemplary configuration of the hook-up region R_{HU} included in the semiconductor memory device according to an embodiment. More specifically, FIG. 10A is an enlarged plan view of an area C illustrated in FIG. 7A described above, FIG. 10B is a cross-sectional view taken along line D-D′ of FIG. 10A, and FIG. 10C is a cross-sectional view taken along line E-E′ of FIG. 10A.

As illustrated in FIG. 10A, in the hook-up region R_{HU} is provided with a plurality of lead line regions R_{LL} aligned in the Y-direction and a contact region R_{CC} provided between two lead line regions R_{LL} adjacent in the Y-direction.

As illustrated in FIGS. 10A to 10C, in the lead line region R_{LL}, insulating layers 191 that extend in the Z-direction, through insulating layers 102 arranged in the plurality of the layers LR and a plurality of the insulating layers 101 interposed between a plurality of the layers 102 are provided side by side in the X-direction so as to be aligned in the extending directions of the lead line regions R_{LL}. Each of the insulating layers 102 is, for example, a silicon nitride layer or the like.

Each of the insulating layers 191 is, for example, a silicon oxide layer or the like, and a conductive layer 196 such as a titanium nitride layer covering a side wall of the insulating layer 191 is provided in the plurality of the layers LR. In the plurality of the layers LR, the conductive layers 196 covering the individual insulating layers 191 are connected to each other in the X-direction. Accordingly, in the plurality of the layers LR, the conductive layers 196 continuously extend in the lead line regions R_{LL} in the X-direction. In addition, these conductive layers 196 are each electrically connected to a bit line LBIy arranged in the same layer LR, from among the plurality of the bit lines LBIy described above. In other words, the conductive layer 196 is connected to a corresponding channel layer CN via the bit lines LBIy and LBIx.

In the contact region R_{CC}, a plurality of the contacts CC aligned in the X-direction along the conductive layer 196 are arranged. Each of these contacts CC includes a conductive layer 192 that serves as a core material of the contact CC, a barrier metal layer 193 that covers a side wall of the conductive layer 192, and an insulating layer 195 that covers a side wall of the barrier metal layer 193. The conductive layer 192 is, for example, a tungsten layer or the like, the barrier metal layer 193 is, for example, a titanium nitride layer or the like, and the insulating layer 195 is, for example, a silicon oxide layer or the like.

The conductive layer 192 and the barrier metal layer 193, extend in the Z-direction through the plurality of insulating layers 102 and insulating layers 101, and reach an insulating layer 102 positioned at a predetermined depth. The barrier metal layer 193 has a lower end portion having a disk shape and expands in an insulating layer 102 positioned at a depth where the contact CC reaches. The disk-shaped portion of the barrier metal layer 193 has one end portion connected to an adjacent conductive layer 192. The insulating layer 195 covers the side wall of the barrier metal layer 193 and extends in the Z-direction through a plurality of the insulating layers 102 and insulating layers 101, and is terminated in an insulating layer 102 one layer above the insulating layer 102 where the conductive layer 192 and the barrier metal layer 193 reach. The insulating layer 195 has protrusions protruding into insulating layers 102 at height positions of the respective insulating layers 102 through which the insulating layer 195 passes.

As illustrated in FIGS. 10B and 10C, the contacts CC have different depths where the contacts CC reach, in the plurality of the insulating layers 102 and insulating layers 101.

For example, between the two lead line regions R_{LL}, two contacts CC adjacent in the Y-direction reach insulating layers 102 having different depths by one layer. These two contacts CC are each connected to an adjacent conductive layer 196 at the disk-shaped portion of the barrier metal layer 193. In addition, two contacts CC adjacent in the X-direction along a conductive layer 196 reach insulating layers 102 having different depths by two layers.

As described above, one contact CC having a smaller depth where the contact CC reaches, from among two contacts CC adjacent in the X-direction or the Y-direction, has a disk-shaped portion of the barrier metal layer 193 that is terminated in contact with an insulating layer 195 of the other contact CC having a larger depth where the contact CC reaches. This configuration enables suppression of conduction between two contacts CC caused by contact between the portions of the conductive layers 192 or the barrier metal layers 193 of the contacts CC.

Note that regardless of the examples of FIGS. 10B and 10C, the disk-shaped portion of each barrier metal layer 193 may not have a uniform thickness. In an example, the disk-shaped portion may be formed thicker in the vicinity of the lower end portion of the conductive layer 192 as compared with the portion expanding in the insulating layer 102.

As illustrated in FIG. 10A, these contacts CC each have the barrier metal layer 193 whose disk-shaped portion has an outer edge cut out at a portion in contact with the conductive layer 196, another contact CC, or the like. Meanwhile, at a portion not facing the conductive layer 196, another contact CC, or the like, the lower end portion of the barrier metal layer 193 expands into a disk shape as described above and is terminated in an insulating layer 102 positioned at a depth where the contact CC reaches.

Note that these contacts CC are connected to a plurality of the bit lines BL extending in the Y-direction in an upper layer portion of the hook-up region R_{HU}, through plugs, which are not illustrated, or the like or directly.

The configuration as described above enables electrical drawing of the bit lines LBIx and LBIy that are connected to the channel layers CN stacked in multiple stages and that are arranged in different layers LR, to the upper surface of the stacked structure of the plurality of the insulating layers 102 and insulating layers 101. At this time, the disk-shaped portion of the barrier metal layer 193 of each contact CC functions as the bit line LBIstr described above.

In FIGS. 2, 3, 7B, and the like described above, for ease of illustration and description, the plurality of the bit lines LBIstr has been illustrated as a stepwise shape having different extension distances in the X-direction, but more specifically, for example, the configurations illustrated in FIGS. 10A to 10C described above enable achievement of the functions of the bit lines LBIstr described above.

### (Configuration Example of Booster Circuit)

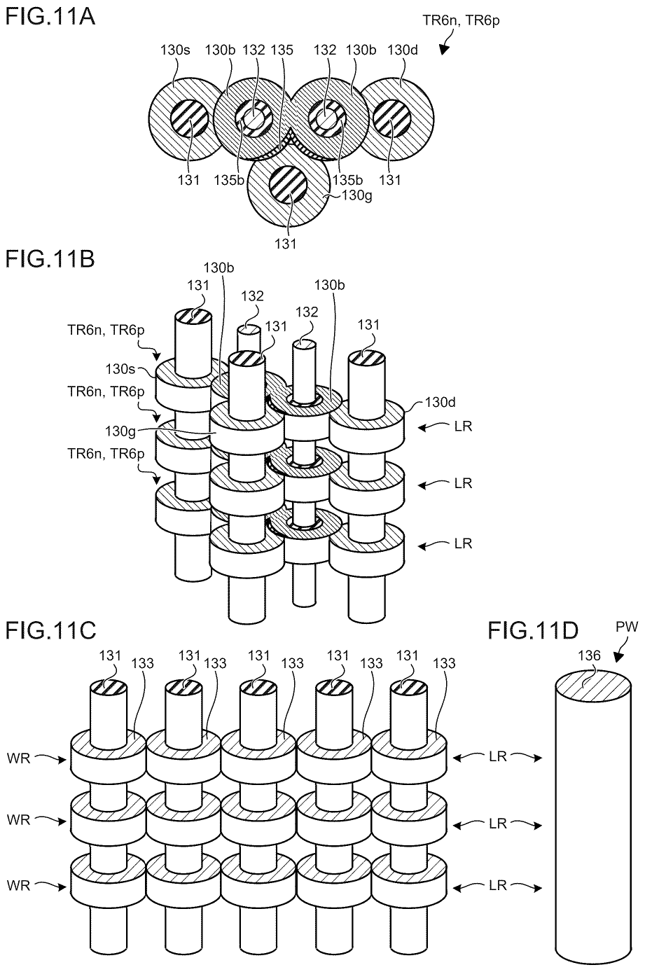

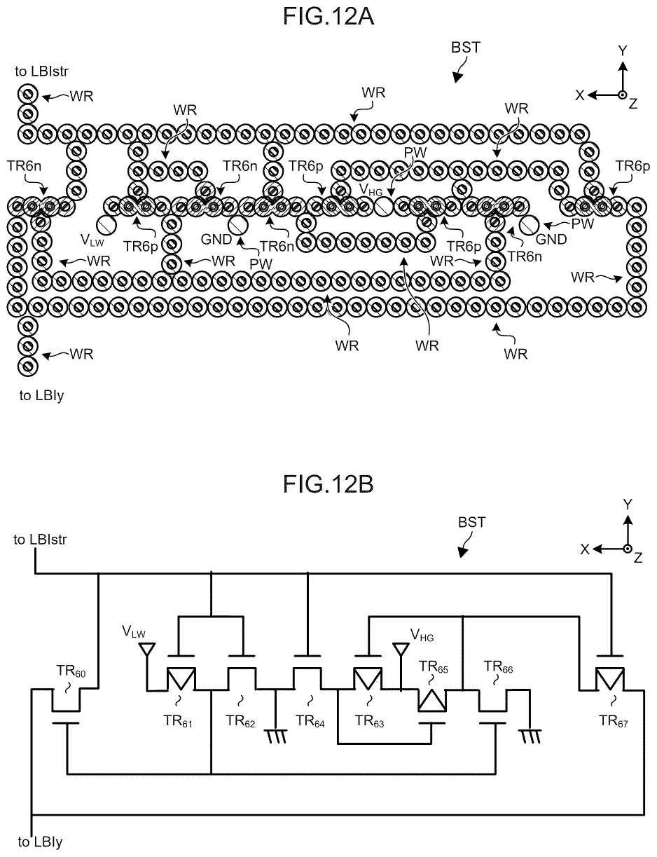

Next, a configuration example of each booster circuit BST included in the semiconductor memory device 1 will be described with reference to FIGS. 11A to 12B. FIGS. 11A to 11D are schematic diagrams each illustrating an example of each unit included in the booster circuit BST of the semiconductor memory device 1 according to an embodiment.

More specifically, FIG. 11A is a plan view of transistors TR6n and TR6p included in the booster circuit BST, and FIG. 11B is a perspective view of the transistors TR6n and TR6p. Note that the transistor TR6n is a low-voltage N-channel MOSFET, and corresponds to the physical configurations of the transistors TR₆₀, TR₆₂, TR₆₄, and TR₆₆ illustrated in FIG. 5 described above. Furthermore, the transistor TR6p is a low-voltage P-channel MOSFET and corresponds to the physical configurations of the transistors TR₆₁, TR₆₃, TR₆₅, and TR₆₇ illustrated in FIG. 5 described above.

FIG. 11C is a perspective view of wirings WR included in the booster circuit BST, and FIG. 11D is a perspective view of a power line PW included in the booster circuit BST.

As illustrated in FIGS. 11A and 11B, each of the transistors TR6n and TR6p includes a diffusion layer 130g serving as a gate electrode of each of the transistors TR6n and TR6p, a diffusion layer 130s serving as a source, a diffusion layer 130d serving as a drain, and an insulating layer 135 serving as a gate insulating layer.

Furthermore, each of the transistors TR6n and TR6p includes a back gate, and includes two conductive layers 132 serving as a back gate electrode, a semiconductor layer 130b serving as a channel of the back gate, and two insulating layers 135b serving as a gate insulating layer for the back gate.

As described above, each of the transistors TR6n and TR6p of the booster circuit BST has a threshold voltage that is adjusted to appropriately perform on/off operation according to the reference voltage VSS or the power supply voltage VDD applied from the bit line LBIy and the low-level voltage V_{LW} or the high-level voltage V_{HG} applied from each of a plurality of power lines. The back gates included in the transistors TR6n and TR6p have a role to adjust the threshold voltages of these transistors TR6n and TR6p.

The diffusion layers 130g, 130s, and 130d included in the transistor TR6n are each, for example, a polysilicon layer or the like in which an N-type impurity such as phosphorus is diffused. The diffusion layers 130g, 130s, and 130d included in the transistor TR6p are each, for example, a polysilicon layer or the like in which a P-type impurity such as boron is diffused. The insulating layers 135 and 135b included in each of the transistors TR6n and TR6p are each, for example, a silicon oxide layer or the like, the conductive layer 132 is, for example, a titanium nitride layer or the like, and the semiconductor layer 130b is a non-doped polysilicon layer or the like.

In addition, the diffusion layers 130g, 130s, and 130d of each of the transistors TR6n and TR6p cover side walls of insulating layers 131 such as a silicon oxide layer having a pillar shape extending through the plurality of the layers LR in the plurality of the layers LR.

Therefore, in the booster circuits BST provided in the plurality of the layers LR, the transistors TR6n or the transistors TR6p are arranged at a position overlapping in the Z-direction in common. In other words, the transistors TR₆₀ included in the plurality of the booster circuits BST are arranged at positions overlapping each other in the Z-direction, the transistors TR₆₁ are arranged at positions overlapping each other in the Z-direction, and the transistors TR₆₂ are arranged at positions overlapping each other in the Z-direction. The same applies to the other transistors TR₆₃ to TR₆₇. At this time, the gate electrodes of a plurality of the transistors TR6n and TR6p arranged at positions overlapping in the Z-direction are provided to be independent for each layer LR.

In addition, the two conductive layers 132 serving as the back gate electrode extend through the plurality of the layers LR at positions between the diffusion layers 130s and 130d of each of the transistors TR6n and TR6p. The side walls of these conductive layers 132 having a pillar shape are each covered with the insulating layer 135b in the plurality of the layers LR. Furthermore, in the plurality of the layers LR, the semiconductor layers 130b each serving as a channel layer of each back gate cover the side walls of the insulating layers 135b and are connected through surfaces facing each other.

Therefore, in the booster circuits BST provided in the plurality of the layers LR, the back gates included in the plurality of transistors TR6n and TR6p are also arranged at positions overlapping each other in the Z-direction. At this time, each of the plurality of the back gates overlapping each other in the Z-direction shares the gate electrode, and the channel and the gate insulating layer are independent of each other.

The insulating layer 135 serving as the gate insulating layer of each of the transistors TR6n and TR6p is arranged on a surface of the semiconductor layer 130b facing the diffusion layer 130g serving as the gate electrode of each of the transistors TR6n and TR6p. Therefore, the gate insulating layers of the plurality of the transistors TR6n and TR6p arranged at the positions overlapping in the Z-direction are also independent for each layer LR.

As described above, the transistors TR6n and TR6p are obtained that are stacked in multiple stages in the plurality of the layers LR and allowed to be independently driven for each of the plurality of the layers LR.

As illustrated in FIG. 11C, each of a plurality of the wirings WR includes a plurality of conductive layers 133 each of which covers a side wall of the insulating layer 131 extending through the plurality of the layers LR, in the plurality of the layers LR. The conductive layers 133 arranged in the same layer LR are connected to each other, and therefore, the wirings WR each extending in a predetermined direction in each of the plurality of the layers LR are formed. One end portion of the wiring WR is connected to the diffusion layer 130g that is the gate electrode of each of the transistors TR6n and TR6p, the diffusion layer 130s that is the source, or the diffusion layer 130d that is the drain, and therefore, the plurality of the transistors TR6n and TR6p are connected to each other to form the booster circuit BST.

At this time, in the booster circuit BST provided in each of the plurality of the layers LR, the wirings WR in a common portion are arranged independently of each other at positions overlapping in the Z-direction.

As illustrated in FIG. 11D, the power line PW includes a conductive layer 136 such as a titanium nitride layer extending through the plurality of the layers LR. In other words, in the booster circuits BST provided in the plurality of the layers LR, the power line PW is commonly provided, and collectively supplies the low-level voltage V_{LW} or the high-level voltage V_{HG} described above, to the booster circuits BST.

FIGS. 12A and 12B are plan views illustrating an exemplary physical configuration of a booster circuit BST included in the semiconductor memory device 1 according to an embodiment. Note that FIGS. 12A and 12B illustrate a booster circuit BST arranged in any layer LR from among the plurality of the layers LR.

As illustrated in FIGS. 12A and 12B, for ease of wiring between units and efficient arrangement of the booster circuit BST in a limited space, upon physical configuration of the booster circuit BST, a circuit layout of the booster circuit BST is changed from the example of FIG. 5 described above so that the sources and drains of the plurality of the transistors TR6n and TR6p included in the booster circuit BST are arranged in line in the X-direction. FIG. 12B is a circuit diagram of the booster circuit BST with the circuit layout changed as described above, and has a configuration equivalent to that of the circuit diagram illustrated in FIG. 5 described above. FIG. 12A illustrates the physical configuration of the booster circuit BST with units arranged to correspond to the circuit layout of FIG. 12B.

As illustrated in FIG. 12A, a transistor TR6n corresponding to the transistor TR₆₀ of the booster circuit BST is arranged with the source facing toward the bit line LBIy to which the booster circuit BST is connected, with the drain facing toward a side away from the bit line LBIy, and with the gate facing toward the bit line LBIx to which the bit line LBIy is connected.

Transistors TR6p, TR6n, TR6n, and TR6p corresponding to the transistors TR₆₁, TR₆₂, TR₆₄, and TR₆₃ of the booster circuit BST are arranged in this order from the side of the bit line LBIy, on a side away from the bit line LBIy relative to the transistor TR6n corresponding to the transistor TR₆₀.

The transistors TR6p corresponding to the transistors TR₆₁ and TR₆₃, from among these transistors TR6p and TR6n, are each arranged with the source facing toward the bit line LBIy, with the drain facing toward the side away from the bit line LBIy, and with the gate facing toward the bit line LBIstr to which the bit line LBIy is connected. In addition, the transistors TR6n corresponding to the transistors TR₆₂ and TR₆₄ are each arranged with the drain facing toward the bit line LBIy, with the source facing toward the side away from the bit line LBIy, and with the gate facing toward the bit line LBIstr to which the bit line LBIy is connected.

In addition, transistors TR6p and TR6n corresponding to the transistors TR₆₅ and TR₆₆ of the booster circuit BST are arranged in this order from the side of the bit line LBIy, on the side further away from the bit line LBIy relative to the transistor TR6p corresponding to the transistor TR₆₃.

The transistor TR6p corresponding to the transistor TR₆₅, from among these transistors TR6p and TR6n, is arranged with the source facing toward the bit line LBIy, with the drain facing toward the side away from the bit line LBIy, and with the gate facing toward the bit line LBIx to which the bit line LBIy is connected. In addition, a transistor TR6n corresponding to the transistor TR₆₆ is arranged with the drain facing toward the bit line LBIy, with the source facing toward the side away from the bit line LBIy, and with the gate facing toward the bit line LBIx to which the bit line LBIy is connected.

In addition, a transistor TR6p corresponding to the transistor TR₆₇ of the booster circuit BST is arranged at a position farthest from the bit line LBIy, with the source facing toward the bit line LBIy, with the drain facing toward the side away from the bit line LBIy, and with the gate facing toward the side of the bit line LBIstr to which the bit line LBIy is connected.

Connecting the plurality of the transistors TR6n and TR6p arranged as described above with the wirings WR described above to have a wiring configuration illustrated in FIG. 12B can obtain the booster circuit BST having the circuit layout of FIG. 12B.

In other words, the drain of the transistor TR6n corresponding to the transistor TR₆₀ is connected to the side of the bit line LBIy leading to the bit line LBIstr, and the source is connected to a side of the bit line LBIy leading to the bit line LIBx.

In addition, the sources and the drains of the transistors TR6p, TR6n, TR6n, TR6p, TR6p, and TR6n corresponding to the transistors TR₆₁, TR₆₂, TR₆₄, TR₆₃, TR₆₅, and TR₆₆ arranged in line in the X-direction are sequentially connected, the sources of the transistors TR6p corresponding to the transistors TR₆₁, TR₆₃, and TR₆₅ are connected to the power line PW described above, and the drains of the transistors TR6n corresponding to the transistors TR₆₂, TR₆₄, and TR₆₆ are connected to the power line PW and grounded.

At this time, the power line PW that supplies the low-level voltage V_{LW} is connected to the transistor TR6p corresponding to the transistor TR₆₁, from among the transistors TR₆₁, TR₆₃, and TR₆₅. In addition, the power line PW that supplies the high-level voltage V_{HG} is commonly connected to the transistors TR6p corresponding to the transistors TR₆₃ and TR₆₅.

Furthermore, the transistors TR6n corresponding to the transistors TR₆₂ and TR₆₄, from among the transistors TR₆₂, TR₆₄, and TR₆₆, are grounded through a common power line PW, and the transistor TR₆₆ is grounded through a power line PW different from these power lines.

Furthermore, the gates of the transistors TR6n corresponding to the transistors TR₆₀ and TR₆₆ are connected to each other. Furthermore, the gates of the transistors TR6p, TR6n, and TR6n corresponding to the transistors TR₆₁, TR₆₂, and TR₆₄ are connected to the side of the bit line LBIy leading to the bit line LBIstr. Furthermore, the sources of the transistors TR6n and TR6p corresponding to the transistors TR₆₄ and TR₆₃ are connected to the gate of the transistor TR6n corresponding to the transistor TR₆₅.

In addition, the drains of the transistors TR6p and TR6n corresponding to the transistors TR₆₅ and TR₆₆ are connected to the gate of the transistor TR6p corresponding to the transistor TR₆₃. The drains of the transistors TR6p and TR6n corresponding to the transistors TR₆₅ and TR₆₆ are also connected to the source of the transistor TR6p corresponding to the transistor TR₆₇. Furthermore, the drain of the transistor TR6p corresponding to the transistor TR₆₇ is connected to the side of the bit line LBIy leading to the bit line LBIx.

As described above, the physical configuration of the booster circuit BST having the circuit configuration equivalent to that of the booster circuit BST illustrated in FIG. 5 is obtained.

Incidentally, in order to boost the power supply voltage VDD applied from a sense amplifier circuit SA to a predetermined channel layer CN via a bit line BL, it is conceivable to provide the booster circuit BST at any portion of the sense amplifier circuit SA or the bit line BL.

However, the sense amplifier circuits SA are arranged on a plane side-by-side corresponding to the individual memory strings MS. When the booster circuit BST is inserted into the sense amplifier circuit SA having a configuration as described above, the area of the sense amplifier module 530 is undesirably increased.

Furthermore, as described above, the plurality of the bit lines BL is arranged at an extremely narrow pitch equal to or less than the reticle limit, for example. Therefore, it is difficult to secure a space for inserting the booster circuit BST around each bit line BL.

Therefore, in the semiconductor memory device 1 according to the embodiment, the booster circuit BST is inserted into each bit line LBIy having relatively extra space on the periphery, in each bit line region R_{BL} extending in the Y-direction on one side of each block region R_{BLK} in the X-direction, on the outside of the block regions R_{BLK} where a large number of configurations are densely arranged.

In addition, stacking the plurality of the booster circuits BST in multiple stages by using the stacked structure of the block region R_{BLK} and the bit line region R_{BL} enables efficient arrangement of the booster circuits BST corresponding to the individual bit lines LBIy. Furthermore, alignment of the plurality of the transistors TR6n and TR6p included in the booster circuit BST in line in the X-direction as described above effectively uses the space in the bit line region R_{BL} on the one side of each block region R_{BLK} in the X-direction.

### Method of Manufacturing Semiconductor Memory Device

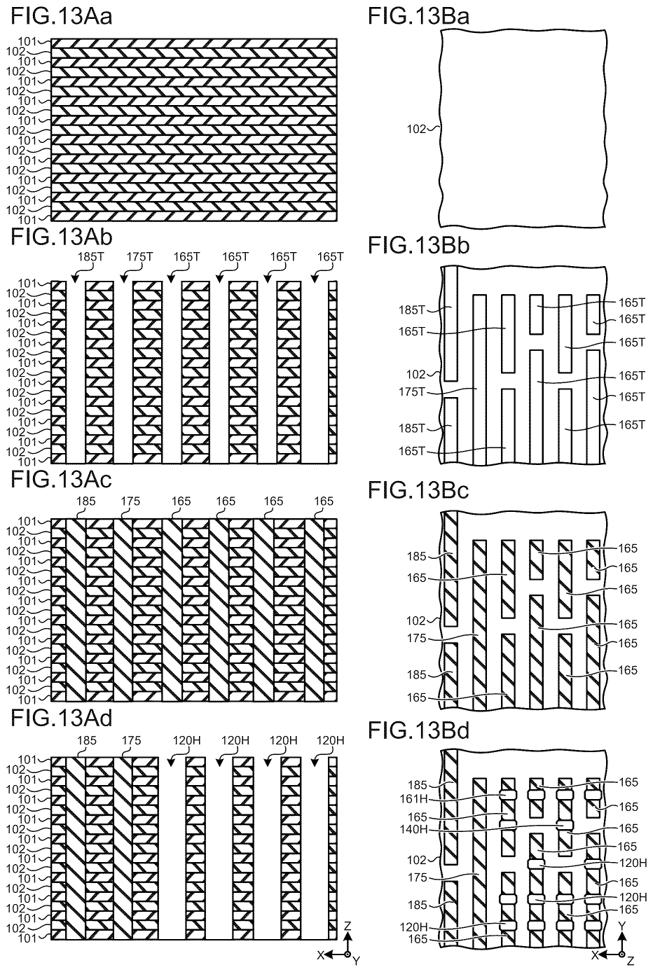

Next, a method of manufacturing the semiconductor memory device 1 according to an embodiment will be described with reference to FIG. 13Aa to 23Bd. FIG. 13Aa to 23Bd are schematic diagrams sequentially illustrating parts of an exemplary procedure of the method of manufacturing a semiconductor memory device 1 according to an embodiment.

As described in detail below, the method for manufacturing the semiconductor memory device 1 according to the embodiment includes forming various configurations included in the block region R_{BLK}, forming the contacts CC and the like included in the hook-up region R_{HU}, and forming the booster circuit BST and the like included in the bit line region R_{BL}. The forming steps of these configurations are interchangeable with each other in the order.

### (Method of Forming Each Unit in Block Region)

First, a method of forming the various configurations included in the block region R_{BLK} will be described with reference to FIG. 13Aa to 17Bd. Note that, in each of FIG. 13Aa to 17Bd, Aa to Ad are cross-sectional views taken along the X-direction including a portion to be served as the block region R_{BLK} later, and Ba to Bd are plan views of any layer LR including the portion to be served as the block region R_{BLK} later.

As illustrated in FIG. 13Aa and 13Ba, a plurality of the insulating layers 102 and a plurality of the insulating layers 101 are alternately stacked one by one. As described above, each of the insulating layers 102 is a silicon nitride layer or the like, and each of the insulating layers 101 is a silicon oxide layer or the like.

As illustrated in FIG. 13Ab and 13Bb, a plurality of slits 185T, 175T, and 165T extending in the Y-direction through the plurality of the insulating layers 102 and 101 are formed. Each of these slits 185T, 175T, and 165T has a pattern similar to that of the insulating layers 185, 175, and 165 described above (see FIG. 9 and the like), and the slits 185T, 175T, and 165T are formed to be separated from each other in the X-direction.

As illustrated in FIG. 13Ac and 13Bc, the insulating layers 185, 175, and 165 are formed by filling the slits 185T, 175T, and 165T with a silicon oxide layer or the like.

As illustrated in FIG. 13Ad and 13Bd, a plurality of holes 120H, 140H, and 161H penetrating the plurality of the insulating layers 102 and insulating layers 101 is formed at positions partially overlapping the insulating layers 165 in the Z-direction. These holes 120H, 140H, and 161H are formed at positions coinciding with the word lines WL, the contact electrodes CE, and the insulating layers 161, which are described above (see FIG. 9 and the like), respectively.

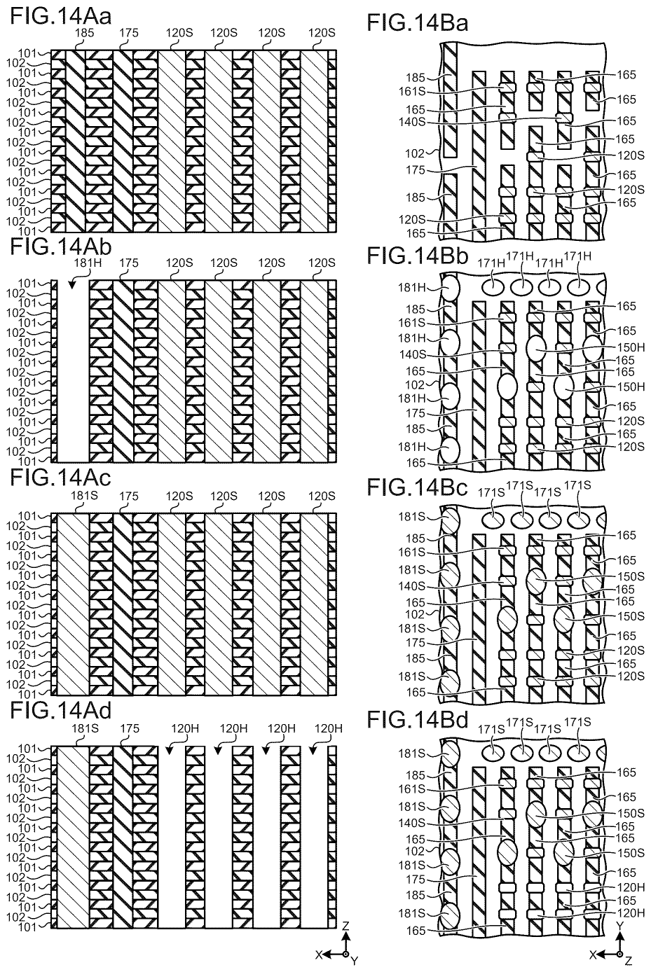

As illustrated in FIG. 14Aa and 14Ba, each of the plurality of holes 120H, 140H, and 161H is filled with an amorphous silicon layer or the like to form sacrificial layers 120S, 140S, and 161S.

As illustrated in FIG. 14Ab and 14Bb, a plurality of holes 181H and 150H extending through the plurality of the insulating layers 102 and insulating layers 101 is formed at positions partially overlapping the insulating layers 185 and 165 in the Z-direction, and in parallel with this, a plurality of holes 171H extending in the X-direction through the plurality of the insulating layers 102 and insulating layers 101 is formed in the vicinity of one end of each of the insulating layers 175 and 165 in the Y-direction. These holes 181H, 171H, and 150H are formed at positions coinciding with the insulating layers 181 and 171 and the gate electrodes GE, which are described above (see FIG. 9 and the like), respectively.

As illustrated in FIG. 14Ac and 14Bc, each of the plurality of holes 181H and 171H is filled with an amorphous silicon layer or the like to form sacrificial layers 181S and 171S.

As illustrated in FIG. 14Ad and 14Bd, the amorphous silicon layer or the like in each of a plurality of the sacrificial layers 120S is removed to open the plurality of holes 120H again.

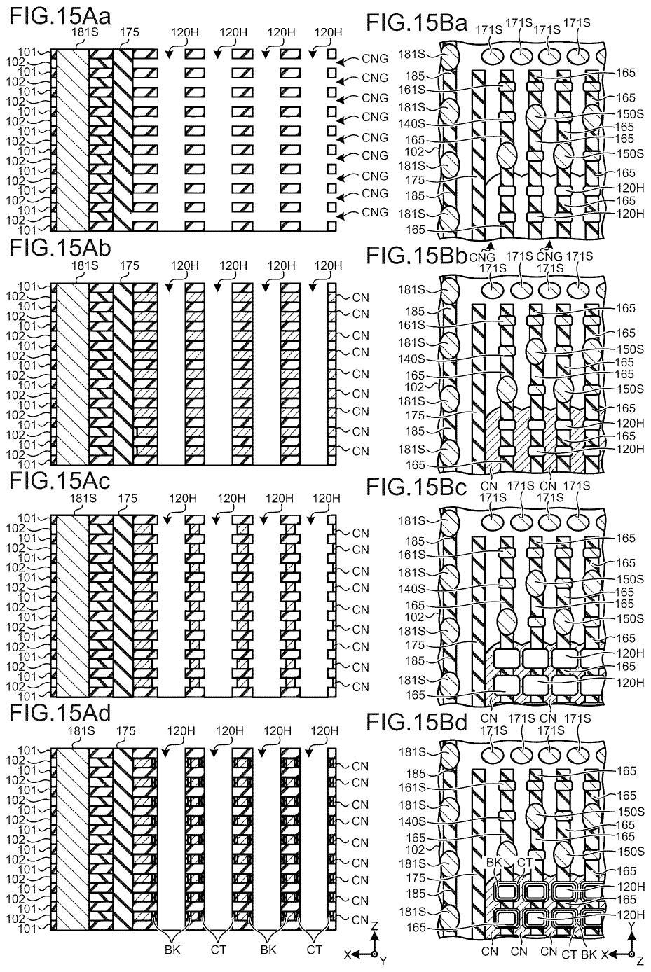

As illustrated in FIG. 15Aa and 15Ba, the plurality of the insulating layers 102 is partially removed via the plurality of holes 120H by using a chemical solution such as hot phosphoric acid to form a plurality of gap layers CNG. At this time, in the Y-direction, processing with the chemical solution is controlled so that the plurality of gap layers CNG do not reach regions where the sacrificial layers 140S and 161S are formed. Furthermore, in the X-direction, the insulating layer 175 prevents further expansion of the plurality of gap layers CNG in the X-direction.

As illustrated in FIG. 15Ab and 15Bb, the plurality of gap layers CNG is filled with a polysilicon layer or the like to form the channel layers CN.

As illustrated in FIG. 15Ac and 15Bc, wet etching or the like is performed through the plurality of holes 120H to retract the channel layers CN from side wall portions of these holes 120H.

As illustrated in FIG. 15Ad and 15Bd, the block insulating layers BK and the charge trap layers CT are sequentially formed in the portions where the channel layers CN are retracted in the plurality of holes 120H. Each of the block insulating layers BK is formed by oxidizing an end face of each of the channels CN retracted, or by filling the retracted portion from which the channel layer CN is retracted, with a silicon oxide layer or the like. Each of the charge trap layer CT is formed by filling the retracted portion of the channel layer CN with a silicon nitride layer or the like via the block insulating layer BK.

Note that, in the above description, when a chemical vapor deposition (CVD) method or the like is used, the silicon oxide layer, the silicon nitride layer, or the like that covers the entire side walls of the holes 120H including the retracted portions of the channel layers CN can be formed. In this case, an unnecessary silicon oxide layer, silicon nitride layer, and the like can be removed from the end surfaces of the insulating layers 101 exposed from the side walls of the holes 120H by wet etching or the like. This configuration enables independent formation of the block insulating layers BK and the charge trap layers CT, at the height positions of the insulating layers 102.

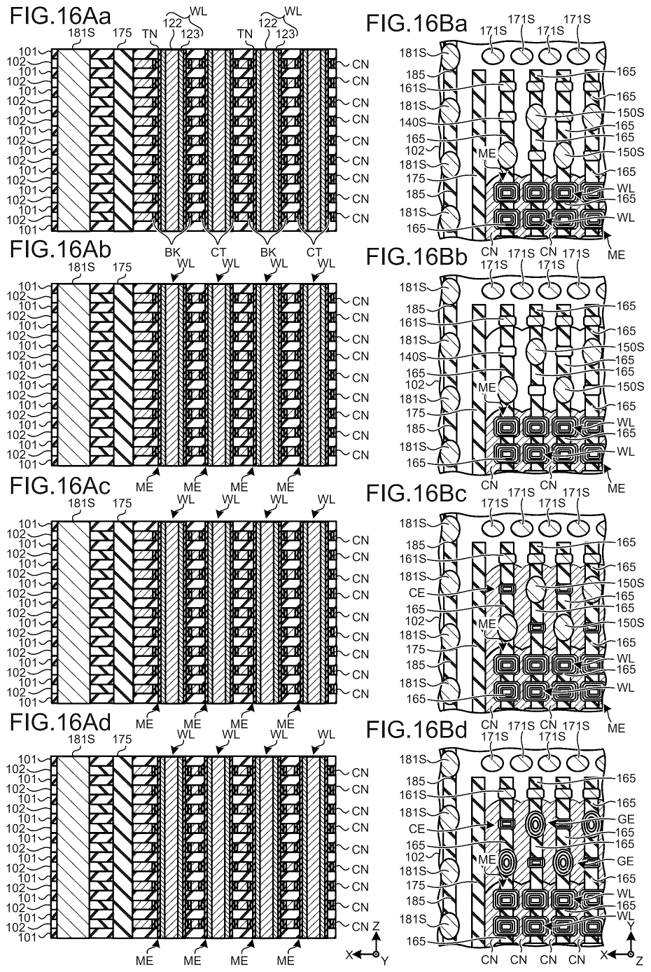

As illustrated in FIG. 16Aa and 16Ba, the tunnel insulating layers TN such as a silicon oxide layer covering the side walls of the plurality of holes 120H are formed. In addition, the barrier metal layer 123 such as a titanium nitride layer covering each of the tunnel insulating layers TN is formed, and a gap remaining in each hole 120H is filled with the conductive layer 122 such as a tungsten layer. Therefore, the memory layer ME including the block insulating layer BK, the charge trap layer CT, and the tunnel insulating layer TN is formed, and each of the word lines WL including the barrier metal layer 123 and the conductive layer 122 is formed.

As illustrated in FIG. 16Bb, the amorphous silicon layer or the like in each of the plurality of the sacrificial layers 140S is removed to open the plurality of holes 140H again.

As illustrated in FIG. 16Bc, the semiconductor layers 144 such as a polysilicon layer covering side walls of the plurality of holes 140H are formed. In addition, the semiconductor layer 140 such as a polysilicon layer containing a P-type impurity such as boron covering each of the semiconductor layers 144 is formed, and the conductive layer 142 such as a titanium nitride layer is filled in a gap remaining in the hole 140H. Therefore, the contact electrodes CE including the semiconductor layers 144 and 140 and the conductive layers 142 are formed.

As illustrated in FIG. 16Bd, the amorphous silicon layer or the like in each of the plurality of sacrificial layers 150S is removed to open the plurality of holes 150H again, the insulating layer 155 such as a silicon oxide layer and the semiconductor layer 150 such as a polysilicon layer containing an N-type impurity such as phosphorus are formed in this order in each of the plurality of holes 150H, and the conductive layer 152 such as a titanium nitride layer is filled in a gap remaining in each of the holes 150H. Therefore, the gate electrode GE including the insulating layer 155 serving as the gate insulating layer on the outer peripheral portion and including the conductive layer 152 and the semiconductor layer 150 is formed.

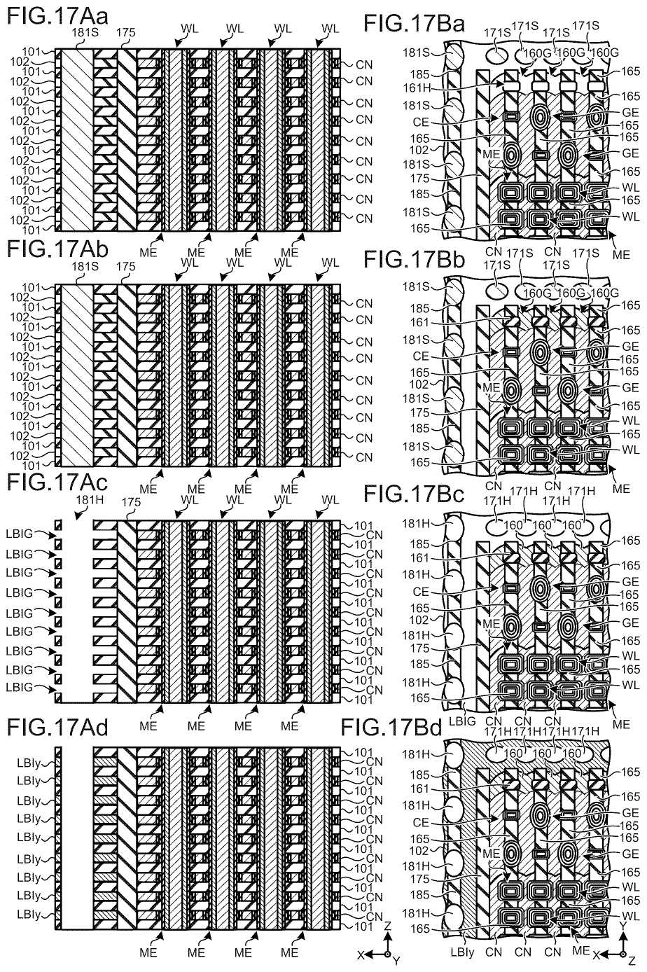

As illustrated in FIG. 17Ba, the amorphous silicon layer or the like in each of the plurality of the sacrificial layers 161S is removed to open the plurality of holes 161H again. In addition, the plurality of the insulating layers 102 is partially removed via the plurality of holes 161H by using the chemical solution such as hot phosphoric acid to form a plurality of gap layers 160G. At this time, in the Y-direction, processing with the chemical solution is controlled so that the plurality of gap layers 160G does not expand beyond an end portion of each of the insulating layers 165 in the Y-direction. Furthermore, in the X-direction, the insulating layer 175 prevents further expansion of the plurality of gap layers 160G in the X-direction.

As illustrated in FIG. 17Bb, the plurality of gap layers 160G is filled with a polysilicon layer or the like containing an N-type impurity such as phosphorus to form the semiconductor layers 160. In addition, the plurality of holes 161H is filled with a silicon oxide layer or the like to form the plurality of insulating layers 161.

As illustrated in FIG. 17Ac and 17Bc, the amorphous silicon layer or the like in each of the plurality of the sacrificial layers 171S and 181S is removed to open the plurality of holes 171H and 181H again.

As illustrated in FIG. 17Ad and 17Bd, the plurality of the insulating layers 102 is removed via the holes 171H and 181H by using a chemical solution such as hot phosphoric acid, gap layers generated are filled with a titanium nitride layer or the like, and the bit lines LBIy and LBIx are generated, respectively.

Thereafter, the plurality of holes 171H and 181H is filled with a silicon oxide layer or the like to form the plurality of insulating layers 171 and 181.

As described above, the various configurations included in the block region R_{BLK} are formed.

### (Method of Forming Contacts in Hook-Up Region)

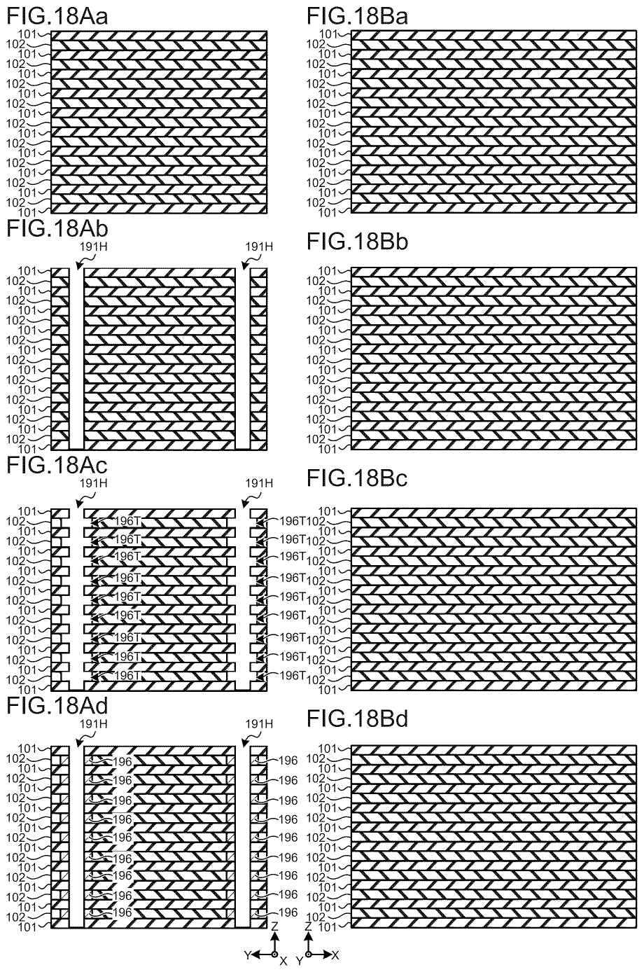

Next, a method of forming the contacts CC included in a hook-up region R_{HU} will be described with reference to FIG. 18Aa to 20Bd. Note that, in each of FIG. 18Aa to 20Bd, Aa to Ad are cross-sectional views taken along the Y-direction including a portion to be served as the hook-up region R_{HU} later, and Ba to Bd are cross-sectional views taken along the X-direction including a portion to be served as the hook-up region R_{HU} later.

As illustrated in FIG. 18Aa and 18Ba, also in the hook-up region R_{HU}, a plurality of the insulating layers 102 and a plurality of the insulating layers 101 are alternately stacked one by one in parallel with the block region R_{BLK} described above.

As illustrated in FIG. 18Ab and 18Bb, a plurality of holes 191H extending in the X-direction through the plurality of the insulating layers 102 and 101 are formed.

As illustrated in FIG. 18Ac and 18Bc, wet etching or the like is performed through the plurality of holes 191H to retract the insulating layers 102 from side wall portions of these holes 191H. Therefore, a plurality of slits 196T is formed that has portions corresponding to the retracted portions of the insulating layers 102, protruding in the Y-direction from a side wall of each of the plurality of holes 191H, that is connected to each other in the X-direction, and that extends in the X-direction at height positions of the insulating layers 102.

As illustrated in FIG. 18Ad and 18Bd, the plurality of slits 196T is filled with a titanium nitride layer or the like to form the plurality of the conductive layers 196 at the height positions of the individual insulating layers 102.

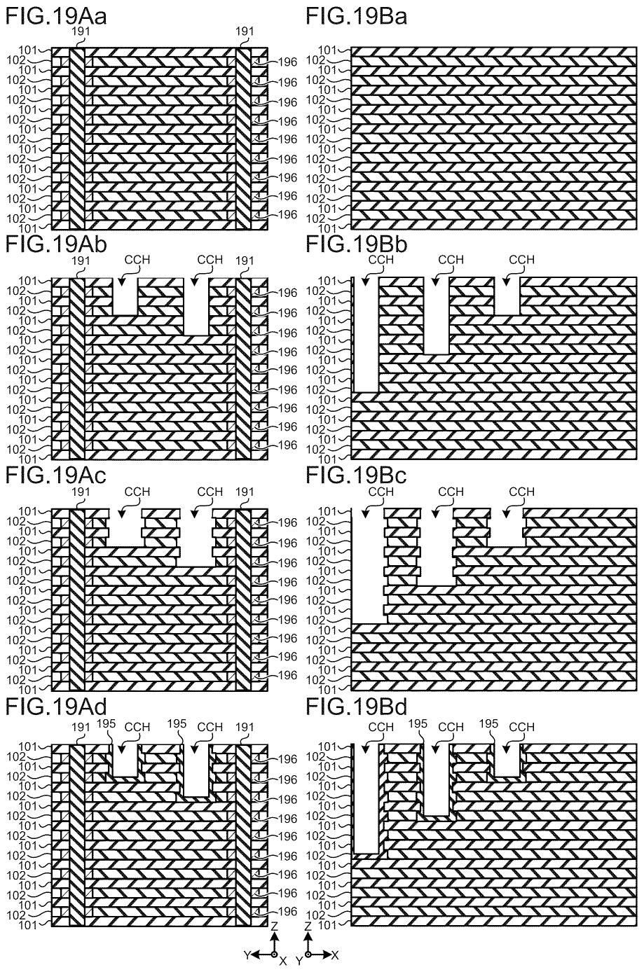

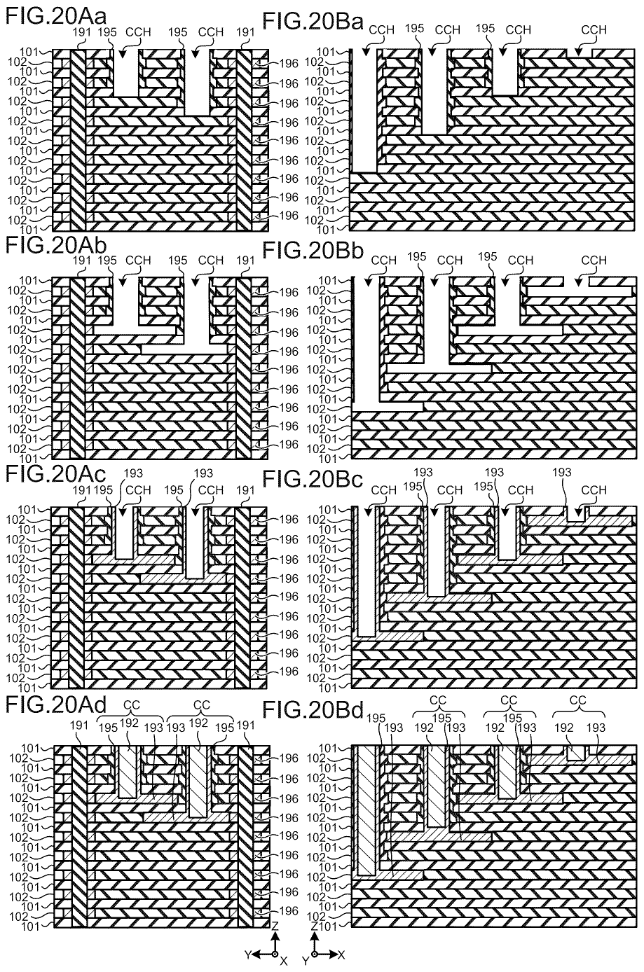

As illustrated in FIG. 19Aa and 19Ba, the plurality of holes 191H is filled with a silicon oxide layer or the like to form a plurality of the insulating layers 191.

As illustrated in FIG. 19Ab and 19Bb, in a region between the conductive layers 196 including the plurality of the insulating layers 191, a plurality of holes CCH extending in the Z-direction through the plurality of the insulating layers 102 and insulating layers 101 and having different depths where the contacts CC reach. Each of these holes CCH is formed at a position where each contact CC is to be formed later. However, these holes CCH have depths where the contacts CC reach are shallower than those of the contacts CC corresponding to these holes CCH by a depth of a pair of the insulating layers 102 and 101.

As illustrated in FIG. 19Ac and 19Bc, wet etching or the like is performed through the plurality of holes CCH to retract the insulating layers 102 from side wall portions of these holes CCH.

As illustrated in FIG. 19Ad and 19Bd, the insulating layers 195 such as a silicon oxide layer are formed that cover side walls and bottom surfaces of the plurality of holes CCH including the retracted portions of the insulating layers 102.

As illustrated in FIG. 20Aa and 20Ba, the plurality of holes CCH is additionally processed to expose insulating layers 102 below the holes CCH through the insulating layers 195 on the bottom surfaces and insulating layers 101 below the bottom surfaces.

As illustrated in FIG. 20Ab and 20Bb, the insulating layers 102 exposed from bottoms of the plurality of holes CCH are retracted to the outside of the holes CCH by wet etching or the like. At this time, upper insulating layers 102 through which these holes CCH pass are protected by the insulating layers 195 and not removed. Therefore, the plurality of holes CCH each having a disk-shaped gap at a lower end portion is formed in the insulating layers 102.

As illustrated in FIG. 20Ac and 20Bc, the barrier metal layers 193 such as a titanium nitride layer are formed that cover the side walls and the bottom surfaces of the plurality of holes CCH and fill the disk-shaped gaps at the lower end portions.

As illustrated in FIG. 20Ad and 20Bd, a gap remaining in each of the holes CCH is filled with the conductive layer 192 such as a tungsten layer. Therefore, the contacts CC including the conductive layers 192, the barrier metal layers 193, and the insulating layers 195 are formed.

As described above, the contacts CC included in the hook-up region R_{HU} are formed.

### (Method of Forming Booster Circuit in Bit Line Region)

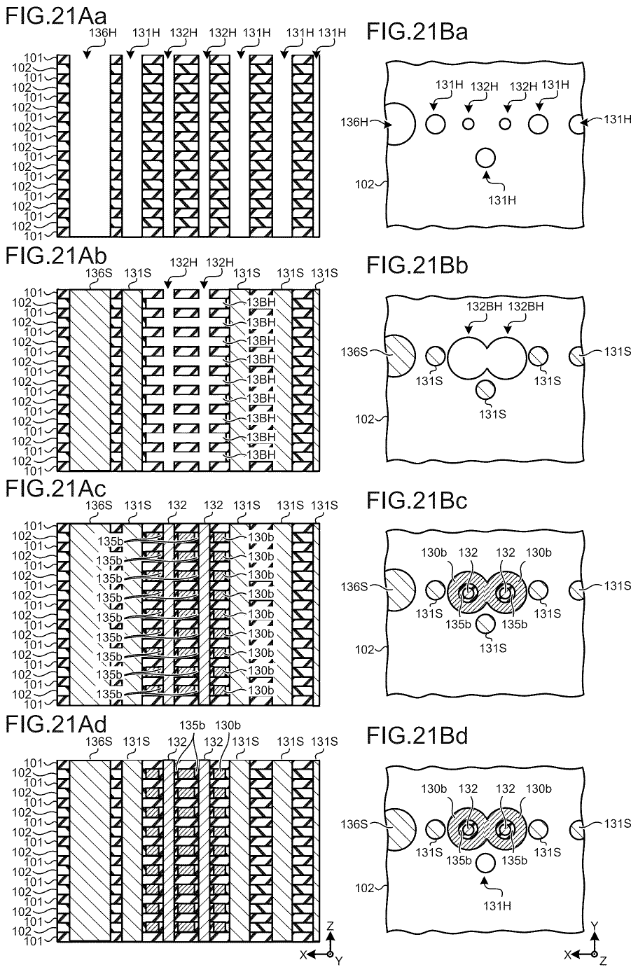

Next, a method of forming a booster circuit BST included in the bit line region R_{BL} will be described with reference to FIG. 21Aa to 23Bd. Note that, in each of FIG. 21Aa to 23Bd, Aa to Ad are cross-sectional views taken along the X-direction including a portion to be served as a transistor TR6p of the booster circuit BST later, and Ba to Bd are plan views of any layer LR including the portion to be served as the transistor TR6p later.

FIG. 21Aa to 23Bd illustrate an example of forming the transistor TR6p having a source to which the power line PW is connected and a drain to which the wiring WR is connected. Note that a transistor TR6n can also be formed in the same manner as the transistor TR6p described below, except for a difference in type between impurities to be diffused in the diffusion layers 130g, 130s, and 130d.

As illustrated in FIG. 21Aa and 21Ba, also in the bit line region R_{BL}, a plurality of the insulating layers 102 and a plurality of the insulating layers 101 are alternately stacked one by one in parallel with the block region R_{BLK} and the hook-up region R_{HU} which are described above.

In addition, two holes 132H are formed that extend in the Z-direction through the plurality of the insulating layers 102 and insulating layers 101 and aligned in the X-direction. Furthermore, in parallel with this, holes 131H are formed that extend in the Z-direction through the plurality of the insulating layers 102 and insulating layers 101, on both sides of the holes 132H in the X-direction and at a position aligned in the Y-direction with an intermediate portion between the holes 132H in the X-direction. These holes 132H and 131H constitute the transistor TR6p later.

Furthermore, in parallel with the formation of the holes 132H and 131H, a hole 136H extending in the Z-direction through the plurality of the insulating layers 102 and 101 is formed further outside the hole 131H on one side in the X-direction of the two holes 132H aligned in the X-direction, and a plurality of holes 131H extending in the Z-direction through the plurality of the insulating in the Z-direction through the plurality of the insulating layers 102 and insulating layers 101 is formed further outside the hole 131H on the other side in the X-direction of the two holes 132H.

The hole 136H constitutes the power line PW later, and the plurality of holes 131H constitute the wirings WR later. Therefore, when the plurality of holes 131H is formed, the number and arrangement of the holes 131H are adjusted according to the arrangement of the wiring WR connected to the drain of the transistor TR6p.

As illustrated in FIG. 21Ab and 21Bb, from among the plurality of the holes 132H, 131H, and 136H, holes 131H and 136H excluding two holes 132H are filled with an amorphous silicon layer or the like to form a plurality of sacrificial layers 131S and a sacrificial layer 136S, respectively.

In addition, wet etching or the like is performed through the plurality of the holes 132H to retract the insulating layer 102 from side wall portions of these holes 132H. Therefore, at the height positions of the insulating layer 102, a plurality of holes 13BH is formed that extends into a circular shape from the side walls of the plurality of holes 132H toward the periphery. Note that the holes 13BH surrounding the adjacent holes 132H are connected to each other.

As illustrated in FIG. 21Ac and 21Bc, a polysilicon layer and a silicon oxide layer are formed in this order in the retracted portions of the insulating layers 102 excluding the portions of the holes 132H, from among the plurality of holes 13BH to form the semiconductor layer 130b and the insulating layer 135b that are independent for each insulating layer 102.

Furthermore, a gap remaining in each of the holes 132H is filled with the conductive layer 132 such as a titanium nitride layer. Therefore, a back gate including the conductive layers 132, the insulating layers 135b, and the semiconductor layers 130b is formed.

As illustrated in FIG. 21Bd, the amorphous silicon layer or the like is removed from a sacrificial layer 131S having been formed at a position aligned with the back gate in the Y-direction to open one hole 131H again.

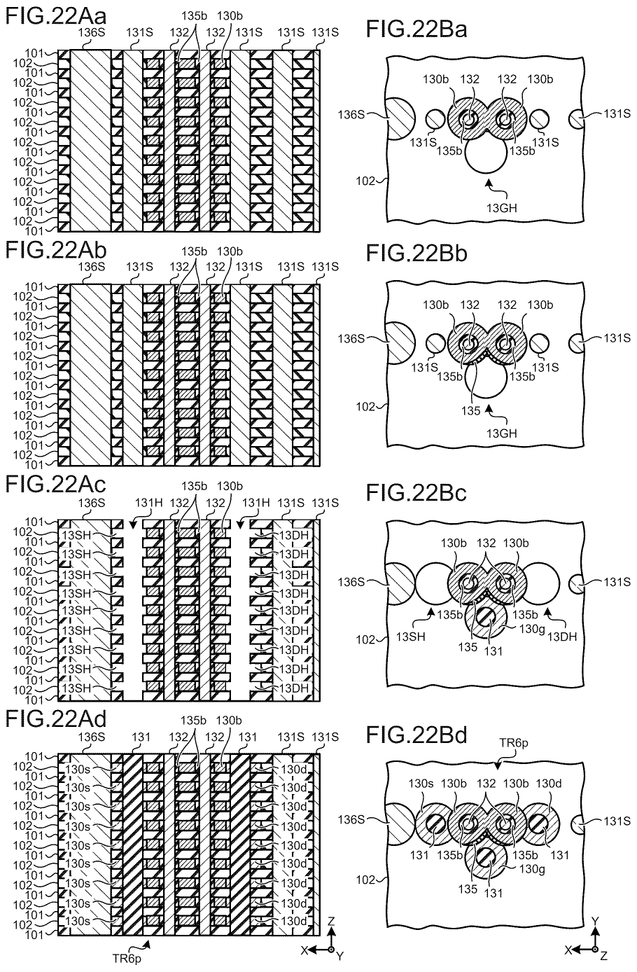

As illustrated in FIG. 22Ba, wet etching or the like is performed through this hole 131H to retract the insulating layer 102 from a side wall portion of the hole 131H. Therefore, at a height position of the insulating layer 102, a hole 13GH is formed that extends into a circular shape from the side wall of the hole 131H toward the periphery.

As illustrated in FIG. 22Bb, side wall portions of the semiconductor layers 130b exposed to one side in the Y-direction of the hole 13GH are oxidized via the hole 13GH. Therefore, the polysilicon layer or the like of the semiconductor layers 130b is oxidized, and the insulating layer 135 such as a silicon oxide layer is formed.

As illustrated in FIG. 22Bc, a retracted portion of the insulating layer 102, from among the hole 13GH described above, excluding the portion of the hole 131H is filled with a polysilicon layer or the like containing a P-type impurity such as boron, and an independent diffusion layer 130g is formed for each of the insulating layers 102. Furthermore, a gap remaining in the hole 13GH is filled with a silicon oxide layer or the like to form the insulating layer 131.

After the portion of the gate electrode of the transistor TR6p is formed as described above, the amorphous silicon layer or the like is removed from the sacrificial layers 131S having been formed at positions aligned on both sides of the back gate in the X-direction to open the two holes 131H again.

As illustrated in FIG. 22Ac and 22Bc, wet etching or the like is performed through these holes 131H to retract the insulating layers 102 from side wall portions of these holes 131H. Therefore, at the height positions of the insulating layer 102, holes 13SH and 13DH are formed that extend into a circular shape from the side walls of the plurality of holes 131H toward the periphery. Note that, in this step, although there is no difference in configuration between the holes 13SH and 13DH, it is assumed that the holes 13SH and 13DH are formed on the respective sides of the semiconductor layers 130b in the X-direction.

As illustrated in FIG. 22Ad and 22Bd, the retracted portions of the insulating layers 102, from among the holes 13SH and 13DH described above, excluding the portions of the holes 131H are filled with a polysilicon layer or the like containing a P-type impurity such as boron, and independent diffusion layers 130s and 130d are formed for each of the insulating layers 102. Furthermore, gaps remaining in the holes 13SH and 13DH are filled with a silicon oxide layer or the like to form the insulating layers 131.

As described above, the transistor TR6p that is a low-voltage P-channel MOSFET is formed.

Note that as described above, upon forming the diffusion layers 130s, 130d, and 130g in the holes 13SH, 13DH, and 13GH, a polysilicon layer or the like containing an N-type impurity such as phosphorus instead of boron or the like can be formed to form the transistor TR6n that is a low-voltage N-channel MOSFET.

Thereafter, the amorphous silicon layer or the like is removed from the sacrificial layer 131S having been formed on the outer side of the diffusion layer 130d in the X-direction to open the plurality of holes 131H again.

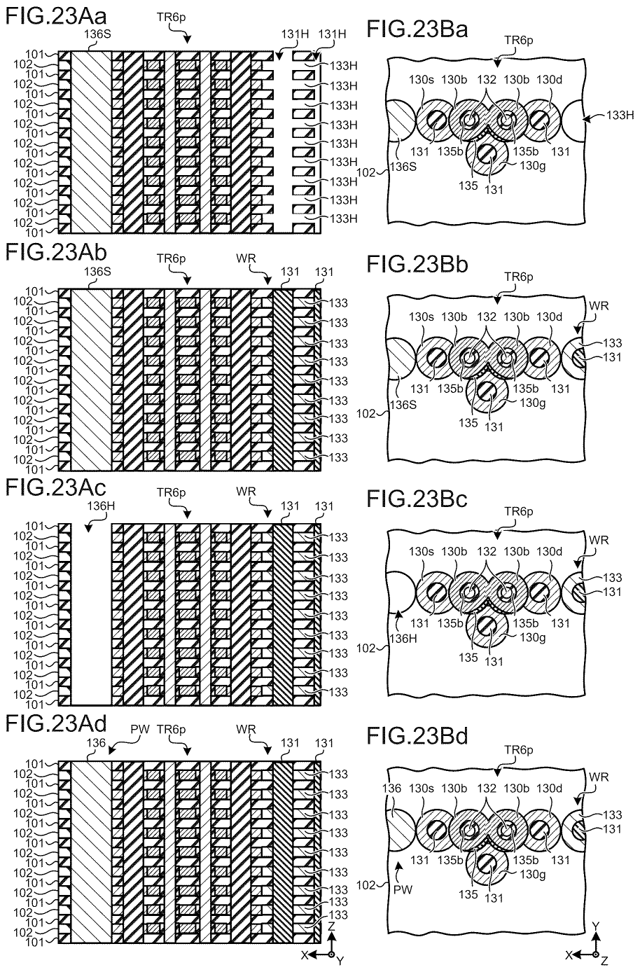

As illustrated in FIG. 23Aa and 23Ba, wet etching or the like is performed through each of the plurality of holes 131H to retract the insulating layers 102 from a side wall portion of each of the holes 131H. Therefore, at the height positions of the insulating layers 102, a plurality of holes 133H is formed that extends into a circular shape from the side walls of the holes 131H toward the periphery.

At this time, for connection between the holes 133H formed around the holes 131H adjacent to each other, the pitch of the holes 131H is adjusted in advance, and a retracted amount of each of the insulating layers 102 from the side wall of each of the holes 131H is adjusted by wet etching.

As illustrated in FIG. 23Ab and 23Bb, the retracted portions of the insulating layers 102 excluding the portions of the holes 131H are filled with a titanium nitride layer or the like, and the conductive layers 133 independent of each other are formed for each of the insulating layers 102. Furthermore, gaps remaining in the holes 131H are filled with a silicon oxide layer or the like to form the insulating layers 131.

The configuration described above enables formation of the wiring WR in which a plurality of the conductive layers 133 are connected, for each of the insulating layers 102.

As illustrated in FIG. 23Ac and 23Bc, the amorphous silicon layer or the like is removed from the sacrificial layer 136S having been formed on the outer side of the diffusion layer 130s in the X-direction to open the hole 136H again. At this time, for contact between a side wall on one side of the hole 136H in the X-direction and the diffusion layer 130s, a position where the hole 136H is to be formed is adjusted.

As illustrated in FIG. 23Ad and 23Bd, filling the hole 136H with a titanium nitride layer or the like forms the power line PW having the conductive layer 136 extending in the Z-direction through a plurality of the insulating layers 102 and insulating layers 101.

As described above, a plurality of the booster circuits BST included in the bit line region R_{BL} is formed to be stacked in the Z-direction.

Note that when the booster circuit BST is formed, it is preferable to collectively form a plurality of the transistors TR6n and TR6p included in the booster circuit BST, the wirings WR, and a plurality of holes 131H, 132H, and 136H constituting the power line PW. This configuration enables suppression of positional deviation between units included in the booster circuit BST to form the booster circuit BST having a desired layout.

As described above, after formation of a plurality of the contacts CC described above, the semiconductor memory device 1 of the embodiment is manufactured by forming a plurality of the bit lines BL that is connected to the contacts CC.

### Conclusion

In a semiconductor memory device such as a three-dimensional nonvolatile memory including a plurality of memory cells, a high-level voltage is applied to other memory cells connected to the same word line via a bit line upon writing data to the memory cells to increase the channel potential. This configuration suppresses writing of data to memory cells not to be written.

At this time, the channels of the memory strings close to each other are capacitively coupled, and therefore, there is a problem that it is difficult to increase the channel potential of a memory string including memory cells not to be written. If the channel potential is insufficiently increased, program disturb such as a weak write condition of the memory cells not to be written occurs.

In order to sufficiently raise the channel potential, for example, increasing the voltage of the sense amplifier module is considered. However, increase of the voltage of the sense amplifier module makes it difficult to miniaturize the semiconductor memory device due to, for example, increase in the area of the sense amplifier module in the semiconductor memory device.

In addition, for example, in a semiconductor memory device such as a three-dimensional nonvolatile memory in which channels are stacked in multiple stages, the program disturb can be suppressed by increasing the thickness of an insulating layer such as a silicon oxide layer interposed between channels. However, increase of the thickness of a plurality of insulating layers stacked makes it difficult to miniaturize the semiconductor memory device.

The semiconductor memory device 1 according to the embodiment includes the booster circuit BST provided in each of the plurality of the insulating layers 102 and connected to each of the plurality of the bit lines BL. This configuration enables application of a high voltage to the memory cells MC not to be written without increasing the voltage of the sense amplifier module 530.

According to the semiconductor memory device 1 of the embodiment, the plurality of the booster circuits BST is arranged to overlap each other in the stacking direction of the plurality of the insulating layers 102 and the plurality of insulating layers 101. This configuration enables efficient arrangement of the booster circuits BST provided corresponding to the plurality of the bit lines BL, reducing the area occupied by the plurality of the booster circuits BST in the semiconductor memory device 1.

According to the semiconductor memory device 1 of the embodiment, the diffusion layers 130g, diffusion layers 130s, and diffusion layers 130d of the transistors TR6n or TR6p included in the plurality of the booster circuits BST overlap each other in the stacking direction of the plurality of the insulating layers 102 and the plurality of insulating layers 101. In this manner, overlapping arrangement of the individual configurations of the plurality of the booster circuits BST in the Z-direction enables overlapping arrangement of these booster circuits BST in the Z-direction.

According to the semiconductor memory device 1 of the embodiment, the diffusion layers 130g, 130s, and 130d are independently provided in the plurality of insulating layers 102 so as to surround the insulating layers 131 extending in the stacking direction of the plurality of insulating layers 102 and insulating layers 101 through the plurality of insulating layers 102 and insulating layers 101. As described above, the diffusion layers 130g, 130s, and 130d provided independently for each insulating layer 102 by using the insulating layers 131 of pillar shape as a support facilitate overlapping arrangement of the transistors TRn or TR6p that are individually operable in the Z-direction.

According to the semiconductor memory device 1 of the embodiment, the back gate provided in each of the transistors TR6n and TR6p includes the insulating layer 135b and the semiconductor layer 130b that are provided independently in the plurality of the insulating layers 102 so as to surround the conductive layers 132 extending in the stacking direction of the insulating layers 102 and insulating layers 101, in the insulating layers 102 and insulating layers 101. This configuration facilitates overlapping arrangement of the transistors TR6n and TR6p including the back gates in the Z-direction.

According to the semiconductor memory device 1 of the embodiment, each of the plurality of the booster circuits BST is connected to a corresponding bit line LBIy. Alignment with the block region R_{BLK} provided with the plurality of channel layers CN in the X-direction and connection to the bit lines LBIy having a relatively extra surrounding space enables securing an arrangement space for the booster circuits BST without affecting the size of the semiconductor memory device 1.

According to the semiconductor memory device 1 of the embodiment, the diffusion layers 130s and 130d included in each of the plurality of the transistors TR6n and TR6p are arranged in line in a corresponding insulating layer 102, from among the plurality of the insulating layers 102, and a row of the diffusion layers 130s and 130d extends in a direction intersecting the extending direction of the bit line LBIy. This configuration efficiently enables use of a space aligned in the X-direction with the block region R_{BLK} provided with the plurality of channel layers CN, as an arrangement space for the booster circuit BST.

According to the semiconductor memory device 1 of the embodiment, from among the plurality of the booster circuits BST, a booster circuit BST connected to the bit line BL corresponding to the memory cell MC not to be written further boosts the voltage higher than the voltage applied to the memory cell MC to be written, and then applies the voltage to the memory cells MC not to be written. This configuration enables suppression of the program disturb in the memory cells MC not to be written.

### Modification

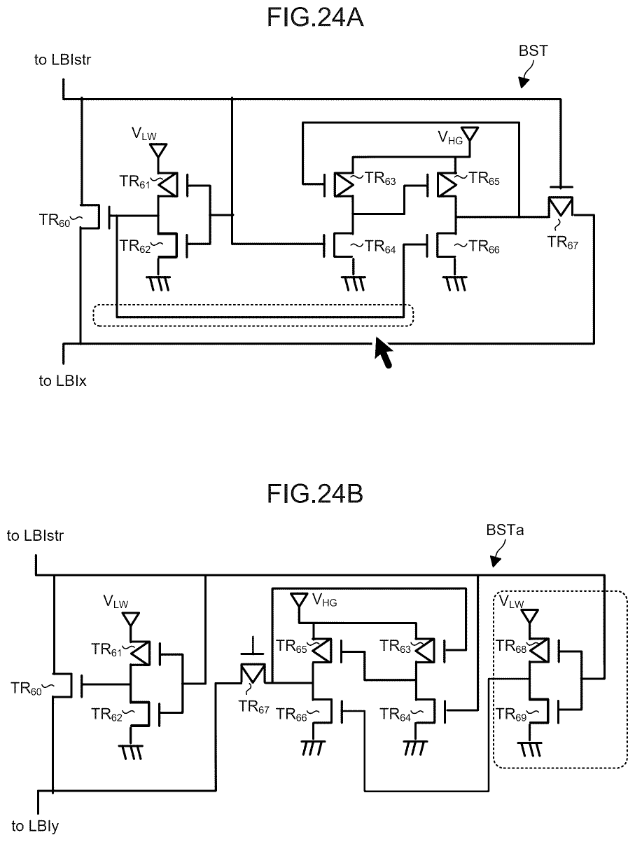

In the embodiments described above, each of the booster circuits BST included in the semiconductor memory device 1 has, for example, a circuit configuration illustrated in FIG. 5. However, as described above, the circuit configuration of the booster circuit BST is not limited to this configuration. Hereinafter, as a semiconductor memory device according to a modification of the embodiment, a semiconductor memory device including a booster circuit BSTa having a circuit configuration different from that of the booster circuit BST described above will be described with reference to FIGS. 24A and 24B.

FIGS. 24A and 24B are circuit diagrams illustrating an exemplary configuration of the booster circuit BSTa included in the semiconductor memory device according to the modification of the embodiment. However, FIG. 24A illustrates the booster circuit BST of the embodiment described above again for comparison, and FIG. 24B illustrates the booster circuit BSTa of the modification.

As illustrated in FIG. 24B, the booster circuit BSTa of the modification includes additional transistors TR₆₈ and TR₆₉ functioning as an inverter, in addition to the configuration of the booster circuit BST of the embodiment described above.

More specifically, the transistor TR₆₈ has a source that is connected to a power line, and for example, the low-level voltage V_{LW} is applied. The transistor TR₆₉ has a drain that is connected to the drain of the transistor TR₆₈, and the transistor TR₆₉ has a source that is grounded. The transistors TR₆₈ and TR₆₉ each have a gate that is connected to a side of the bit line LBIy leading to the bit line LBIstr.

Furthermore, the transistor TR₆₆ has a gate that is connected to the drain of each of the transistors TR₆₈ and TR₆₉ instead of the drain of each of the transistors TR₆₁ and TR₆₂.

Although the booster circuit BSTa of the modification has a circuit length larger in the X-direction by the size of the additional transistors TR₆₈ and TR₆₉, the configuration as described above enables reduction of the wiring of the booster circuit BST of the embodiment indicated by an arrow in FIG. 24A. Therefore, in the booster circuit BSTa of the modification, the circuit length in the Y-direction can be reduced. The Y-direction is the extending direction of the bit line LBIy and the space is more limited than in the X-direction, and therefore, the configuration of the booster circuit BSTa of the modification enabling further space saving is useful.

Assuming that a cylindrical structure such as each of the diffusion layers 130s and 130d formed around the pillar-shaped insulating layers 131 or the semiconductor layer 130b formed around the conductive layer 132 is defined as 1 pitch, an extension of the circuit length in the X-direction by the addition of the transistors TR₆₈ and TR₆₉ is 4 pitches×2 from the source to the drain of each of the transistors TR₆₈ and TR₆₉, that is, 8 pitches+α. Meanwhile, assuming that a cylindrical structure such as the conductive layer 133 formed around the pillar-shape insulating layer 131 is 1 pitch, the reduction in the circuit length in the Y-direction due to the reduction in the number of wirings WR in one row is a space of the wiring WR reduced+the other wirings WR, that is, 2 pitches +α.

In addition, the semiconductor memory device of the modification has the effects similar to those of the above-described embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body in which a plurality of first insulating layers and a plurality of second insulating layers are alternately stacked;
a plurality of channel layers that is provided in the plurality of first insulating layers respectively and extends in a first direction along the plurality of first insulating layers; and
a word line that extends in the stacked body in a stacking direction of the stacked body and intersects the plurality of channel layers;
a plurality of bit lines that is connected to the plurality of channel layers respectively; and
a plurality of booster circuits that is provided in the plurality of first insulating layers and connected to the plurality of bit lines respectively.

2. The semiconductor memory device according to claim 1, wherein
the plurality of booster circuits is arranged so as to overlap each other in the stacking direction.

3. The semiconductor memory device according to claim 2, wherein
each of the plurality of booster circuits includes MOSFET that has a gate electrode, a source, and a drain, and
each of the gate electrodes, each of the sources, and each of the drains of the MOSFETs included in the plurality of booster circuits overlap each other in the stacking direction.

4. The semiconductor memory device according to claim 3, wherein
the gate electrode, the source, and the drain each include:
a first pillar that is insulative and extends in the stacked body in the stacking direction; and
a first diffusion layer that is independently provided in the plurality of first insulating layers and surrounds the first pillar.

5. The semiconductor memory device according to claim 3, wherein
the MOSFET further includes a back gate, and
the back gate includes:
a second pillar that is conductive and extends in the stacked body in the stacking direction;
a gate insulating layer that is independently provided in the plurality of first insulating layers and surrounds the second pillar; and
a semiconductor layer that is independently provided in the plurality of first insulating layers and surrounds the gate insulating layer.

6. The semiconductor memory device according to claim 1, wherein
each of the plurality of booster circuits includes a plurality of MOSFETs, and
each of the plurality of MOSFETs has sources and drains that are arranged in line in a corresponding first insulating layer, from among the plurality of first insulating layers.

7. The semiconductor memory device according to claim 6, wherein
the plurality of booster circuits is arranged at positions overlapping the plurality of channel layers in the first direction, and
a row of the source and the drain of each of the plurality of MOSFETs extends in the first direction.

8. The semiconductor memory device according to claim 1, further comprising:
a plurality of memory cells that is arranged at respective intersections of the plurality of channel layers and the word line; and
a sense amplifier module to which data from the plurality of memory cells is read,
wherein the plurality of bit lines includes:
a plurality of local bit lines that is provided in the plurality of first insulating layers and extends in a second direction intersecting the first direction and the stacking direction, from positions overlapping the plurality of channel layers in the first direction; and
a plurality of global bit lines that extends in the second direction at positions overlapping the plurality of channel layers in the stacking direction and electrically connects the plurality of local bit lines and the sense amplifier module, and
each of the plurality of booster circuits is connected to a corresponding local bit line, from among the plurality of local bit lines.

9. The semiconductor memory device according to claim 8, wherein
the plurality of booster circuits includes a plurality of MOSFETs, and
each of the plurality of MOSFETs has a source and a drain that are arranged in line in a corresponding first insulating layer, from among the plurality of first insulating layers, and
a row of the source and the drain of each of the plurality of MOSFETs extends in a direction intersecting an extending direction of the plurality of local bit lines.

10. The semiconductor memory device according to claim 1 further comprising:
a plurality of memory cells that is arranged at respective intersections between the plurality of channel layers and the word line; and
a sequencer that controls writing of data to the plurality of memory cells,
wherein the sequencer includes the functions of:
supplying a first voltage that permits writing of the data to a memory cell to be written, from among the plurality of memory cells, via a first bit line electrically connected to the memory cell to be written, from among the plurality of bit lines;
supplying a second voltage that is higher than the first voltage and suppresses writing of the data, to a memory cell not to be written, from among the plurality of memory cells, via a second bit line electrically connected to the memory cell not to be written, from among the plurality of bit lines; and
further boosting the second voltage by a booster circuit, from among the plurality of booster circuits, connected to the second bit line, and then applying the boosted second voltage to the memory cell not to be written.
